(19) United States
(12) Patent Application Publication
(10) Pub. No.: US 2026/0221194 A1
(43) Pub. Date: Jul. 30, 2026

(54) MEMORY DEVICE

(71) Applicant: Kioxia Corporation, Tokyo (JP)

(72) Inventor: Fumitaka ARAI, Yokkaichi Mie (JP)

(73) Assignee: Kioxia Corporation, Tokyo (JP)

(21) Appl. No.: 19/329,939

(22) Filed: Sep. 16, 2025

(30) Foreign Application Priority Data
Jan. 24, 2025 (JP) 2025-010716

(51) Int. Cl. G11C 16/10; G11C 16/04; G11C 16/24; G11C 16/30

(52) U.S. Cl. CPC G11C 16/102; G11C 16/0466; G11C 16/24; G11C 16/30

(57) ABSTRACT

A memory device according to one embodiment includes first and second bit lines, a first transistor, a string, a word line, a sense amplifier, and a driver. One end of the first transistor is coupled to the first bit line. The second bit line is coupled to the other end of the first transistor. The string includes a second transistor and a memory cell. The second transistor is coupled to the second bit line. The word line is coupled to the memory cell. The sense amplifier is coupled to the first bit line. The driver is coupled to the first or second bit lines. If the memory cell is set to be a program-inhibit in a write operation, the sense amplifier applies a first voltage to the first bit line, and the driver applies a second voltage higher than the first voltage to the second bit line.

### CROSS-REFERENCE TO RELATED APPLICATION

This application is based upon and claims the benefit of priority from prior Japanese Patent Application No. 2025-010716, filed Jan. 24, 2025, the entire contents of which are incorporated herein by reference.

### FIELD

Embodiments described herein relate generally to a memory device.

### BACKGROUND

A NAND flash memory capable of storing data in a nonvolatile manner is known.

### BRIEF DESCRIPTION OF THE DRAWINGS

FIG. 1 is a block diagram illustrating an example of an overall configuration of a memory system including a memory device according to a first embodiment.

FIG. 2 is a circuit diagram illustrating an example of a circuit configuration of a memory cell array included in the memory device according to the first embodiment.

FIG. 3 is a circuit diagram illustrating an example of a circuit configuration of a data register and a sense amplifier module included in the memory device according to the first embodiment.

FIG. 4 is a circuit diagram illustrating an example of a circuit configuration of a bit line section included in the memory device according to the first embodiment.

FIG. 5 is a perspective view illustrating an outline of a configuration of the memory device according to the first embodiment.

FIG. 6 is a plan view illustrating an example of a planar layout of a memory cell array included in the memory device according to the first embodiment.

FIG. 7 is a cross-sectional view illustrating an example of a cross-sectional configuration of a NAND string included in the memory device according to the first embodiment.

FIG. 8 is a cross-sectional view illustrating an example of a cross-sectional configuration of a memory cell transistor included in the memory device according to the first embodiment.

FIG. 9 is a cross-sectional view illustrating an example of a cross-sectional configuration of a select transistor included in the memory device according to the first embodiment.

FIG. 10 is a cross-sectional view illustrating an example of a cross-sectional configuration of a source line included in the memory device according to the first embodiment.

FIG. 11 is a cross-sectional view illustrating an example of a cross-sectional configuration of the memory cell array included in the memory device according to the first embodiment.

FIG. 12 is a cross-sectional view illustrating an example of a cross-sectional configuration of a local bit line included in the memory device according to the first embodiment.

FIG. 13 is a diagram illustrating an example of a threshold voltage distribution of memory cell transistors MT included in the memory device according to the first embodiment.

FIG. 14 is a diagram illustrating an example of an operation of a NAND string coupled to a bit line of a program-target at a charge time of a write operation of the memory device according to the first embodiment.

FIG. 15 is a diagram illustrating an example of an operation of the NAND string coupled to a bit line of a program-target at a program time of a write operation of the memory device according to the first embodiment.

FIG. 16 is a diagram illustrating an example of an operation of the NAND string coupled to a bit line of a program-inhibit at a charge time of a write operation of the memory device according to the first embodiment.

FIG. 17 is a diagram illustrating an example of an operation of the NAND string coupled to a bit line of a program-inhibit at a program time of a write operation of the memory device according to the first embodiment.

FIG. 18 is a diagram illustrating a concrete example of an operation of a NAND string at a time of a write operation in a second comparative example.

FIG. 19 is a diagram illustrating a concrete example of an operation of the NAND string at a time of a write operation in the first embodiment.

FIG. 20 is a circuit diagram illustrating an example of a circuit configuration of a memory device according to a second embodiment.

FIG. 21 is a plan view illustrating an example of a planar layout of a memory cell array included in the memory device according to the second embodiment.

FIG. 22 is a diagram illustrating an example of an operation of a NAND string coupled to a bit line of a program-target at a charge time of a write operation of the memory device according to the second embodiment.

FIG. 23 is a diagram illustrating an example of an operation of the NAND string coupled to a bit line of a program-target at a program time of a write operation of the memory device according to the second embodiment.

FIG. 24 is a diagram illustrating an example of an operation of the NAND string coupled to a bit line of a program-inhibit at a charge time of a write operation of the memory device according to the second embodiment.

FIG. 25 is a diagram illustrating an example of an operation of the NAND string coupled to a bit line of a program-inhibit at a program time of a write operation of the memory device according to the second embodiment.

FIG. 26 is a circuit diagram illustrating an example of a circuit configuration of a memory device according to a third embodiment.

FIG. 27 is a cross-sectional view illustrating an example of a cross-sectional configuration of a staircase region of a memory cell array included in the memory device according to the third embodiment.

FIG. 28 is a diagram illustrating an example of an operation of a NAND string coupled to a bit line of a program-target at a program time of a write operation of the memory device according to the third embodiment.

FIG. 29 is a diagram illustrating an example of an operation of a NAND string coupled to a bit line of a program-inhibit at a program time of a write operation of the memory device according to a third embodiment.

FIG. 30 is a circuit diagram illustrating an example of a circuit configuration of a memory device according to a fourth embodiment.

FIG. 31 is a circuit diagram illustrating an example of a circuit configuration of an operation selection circuit included in the memory device according to the fourth embodiment.

FIG. 32 is a diagram illustrating an example of an operation of a NAND string coupled to a bit line of a program-target at a program time of a write operation of the memory device according to the fourth embodiment.

FIG. 33 is a diagram illustrating an example of an operation of a NAND string coupled to a bit line of a program-inhibit at a program time of a write operation of the memory device according to the fourth embodiment.

### DETAILED DESCRIPTION

In general, according to one embodiment, a memory device includes a first bit line, a first select transistor, a second bit line, a string, a word line, a sense amplifier, and a driver circuit. One end of the first select transistor is coupled to the first bit line. The second bit line is coupled to the other end of the first select transistor. The string includes a second select transistor and a memory cell transistor. The second select transistor is coupled to the second bit line. The word line is coupled to the memory cell transistor. The sense amplifier is coupled to the first bit line. The driver circuit is coupled to the first bit line or the second bit line. In a case where the memory cell transistor is set to be a program-inhibit in a write operation, the sense amplifier applies a first voltage to the first bit line, and the driver circuit applies a second voltage higher than the first voltage to the second bit line.

Hereinafter, embodiments will be described with reference to the drawings. The embodiments exemplify devices and methods for embodying the technical concepts of the invention. The drawings are schematic or conceptual. The dimensions and ratios in the drawings are not necessarily identical to actual ones. Illustrations of structures are omitted as appropriate. Hatching added in the drawings is not necessarily related to materials and characteristics of structural elements. In the present specification, structural elements having substantially the same function and configuration are marked with the same reference signs. The numerals, characters, etc. added to reference signs are referred to by the same reference signs, and are used to distinguish between similar elements. In the present specification, one of the source and the drain of a transistor is referred to as “one end (of a current path)”, and the other of the source and drain is referred to “the other end (of a current path)”. The structure (source or drain) assigned to the one end and the other end may vary from transistor to transistor.

### <1> First Embodiment

A memory device 1 according to a first embodiment is a kind of an HCF (Horizontal Channel Flash) having such a configuration that a channel extends in a direction parallel to a substrate. The memory device 1 according to the first embodiment extends a control range of voltage of a bit line BL at a time of a write operation, by a circuit capable of applying a higher voltage than a sense amplifier being coupled to an intermediate portion of the bit line BL. Hereinafter, the details of the memory device 1 according to the first embodiment are described.

### <1-1> Configuration

To begin with, a configuration of the memory device 1 according to the first embodiment is described.

### <1-1-1> Overall Configuration of Memory Device 1

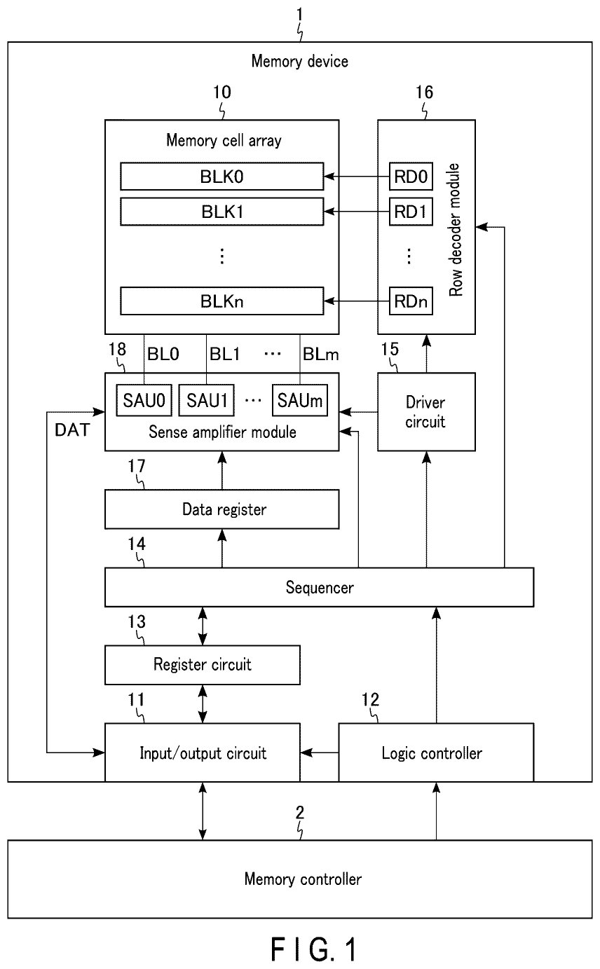

FIG. 1 is a block diagram illustrating an example of an overall configuration of a memory system including the memory device 1 according to the first embodiment. As illustrated in FIG. 1, the memory device 1 is controlled by an external memory controller 2. The memory device 1 includes, for example, a memory cell array 10, an input/output circuit 11, a logic controller 12, a register circuit 13, a sequencer 14, a driver circuit 15, a row decoder module 16, a data register 17, and a sense amplifier module 18.

The memory cell array 10 includes a plurality of blocks BLK0 to BLKn (“n” is an integer of 1 or more). The block is a set of memory cells. The block BLK corresponds to, for example, a unit of data erase. The block BLK includes a plurality of pages. The page corresponds to a unit with which data read and data write are executed. Although an illustration is omitted, the memory cell array 10 is provided with a plurality of bit lines BL0 to BLm (“m” is an integer of 1 or more), and a plurality of word lines WL. Each memory cell is associated with, for example, one bit line BL and one word line WL.

The input/output circuit 11 is an interface circuit that controls transmission and reception of input/output signals to and from the memory controller 2. The input/output signals include, for example, data DAT, status information, address information, a command, and the like. The input/output circuit 11 can input and output the data DAT between the sense amplifier module 18 and the memory controller 2. The input/output circuit 11 can output the status information, which is transferred from the register circuit 13, to the memory controller 2. The input/output circuit 11 can output the address information and the command, which are transferred from the memory controller 2, to the register circuit 13.

The logic controller 12 controls the input/output circuit 11 and the sequencer 14, based on control signals that are input from the memory controller 2. For example, the logic controller 12 controls the sequencer 14 and enables the memory device 1. The logic controller 12 notifies the input/output circuit 11 that the input/output signals, which the input/output circuit 11 has received, are a command, address information, and the like. The logic controller 12 instructs the input/output circuit 11 to input or output the input/output signals.

The register circuit 13 temporarily stores the status information, address information and command. The status information is updated based on the control of the sequencer 14, and is transferred to the input/output circuit 11. The address information includes a block address, a page address, a column address, and the like. The command includes instructions relating to various operations of the memory device 1.

The sequencer 14 controls the overall operation of the memory device 1. Based on the command and address information stored in the register circuit 13, the sequencer 14 executes a read operation, a write operation, an erase operation, and the like. The sequencer 14 may be referred to as a controller, a control circuit, or the like.

The driver circuit 15 generates voltages that are used in the read operation, write operation, erase operation and the like. In addition, the driver circuit 15 supplies the generated voltages to the row decoder module 16 and the sense amplifier module 18.

The row decoder module 16 is a circuit used for selecting the block BLK of an operation target, and for transferring voltage to an interconnect such as the word line WL. The row decoder module 16 includes row decoders RD0 to RDn. The row decoders RD0 to RDn are associated with the blocks BLK0 to BLKn, and are used for selecting the block BLK. Each row decoder RD transfers the voltage generated by the driver circuit 15 to various interconnects provided in the memory cell array 10.

The data register 17 can temporarily store the data DAT. The data register 17 is used at a time of inputting and outputting the data DAT, for example, between the input/output circuit 11 and the sense amplifier module 18. The data register 17 may be referred to as a data latch, a page register, or a cache memory.

The sense amplifier module 18 is a circuit used for supplying voltage to each bit line BL, and for reading data. The sense amplifier module 18 includes sense amplifier units SAU0 to SAUm. The sense amplifier units SAU0 to SAUm are associated with the bit lines BL0 to BLm. Each sense amplifier unit SAU can determine data that is read from a selected memory cell transistor MT, based on the voltage of the associated bit line BL.

Note that a combination of the memory device 1 and the memory controller 2 may constitute one semiconductor device. Examples of such a semiconductor device include a memory card such as an SD™ card, and an SSD (solid state drive).

### <1-1-2> Circuit Configuration of Memory Device 1

Next, an example of a circuit configuration of the memory device 1 according to the first embodiment is described.

### (1: Circuit Configuration of Memory Cell Array 10)

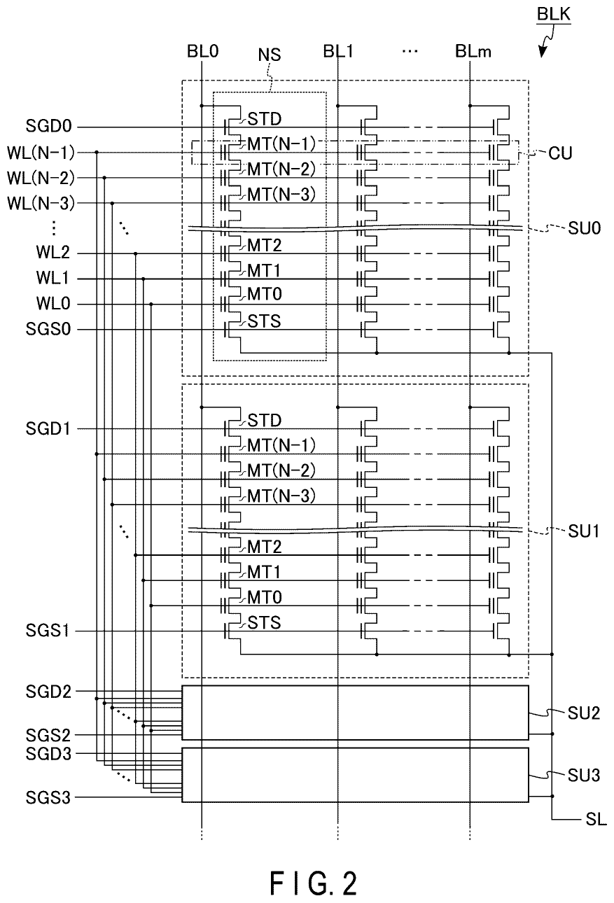

FIG. 2 is a circuit diagram illustrating an example of a circuit configuration of the memory cell array 10 included in the memory device 1 according to the first embodiment. FIG. 2 illustrates one of the blocks BLK included in the memory array 10. As illustrated in FIG. 2, a plurality of bit lines BL0 to BLm, a plurality of word lines WL0 to WL(N-1) (N is an integer of 2 or more), select gate lines SGD0 to SGD3, select gate lines SGS0 to SGS3, and a source line SL are coupled to the block BLK. The select gate lines SGD0 to SGD3 and SGS0 to SGS3, and word lines WL0 to WL(N−1) (N is an integer of 2 or more) are provided for each block BLK. The bit lines BL0 to BLm are shared by a plurality of blocks BLK. The source line SL is shared by a plurality of blocks BLK.

The block BLK includes, for example, four string units SU0 to SU3. Each string unit SU includes a plurality of NAND strings NS. The NAND strings NS are associated with the bit lines BL0 to BLm, respectively. Each NAND string NS is coupled between the associated bit line BL and the source line SL.

Each NAND string NS includes, for example, an N-number of memory cell transistors MT0 to MT(N−1) and select transistors STD and STS. Each memory cell transistor MT is a memory cell including a control gate and a charge storage layer (floating gate), and retains (stores) data in a nonvolatile manner. A threshold voltage of the memory cell transistor MT can be changed based on a charge amount injected in the charge storage layer, or the like. The select transistors STD and STS are used to select the string unit SU.

In each NAND string NS, the select transistor STD, memory transistors MT(N−1) to MT0, and select transistor STS are coupled in series in the named order. Specifically, one end of the select transistor STD is coupled to the associated bit line BL. The other end of the select transistor STD is coupled to one end of the memory cell transistor MT(N−1). The memory cell transistors MT0 to MT(N−1) are coupled in series between the select transistors STD and STS. One end of the select transistor STS is coupled to the other end of the memory cell transistor MT0. The other end of the select transistor STS is coupled to the source line SL.

The select gate lines SGD0 to SGD3 are associated with the string units SU0 to SU3, respectively. Each select gate line SGD is coupled to the gates of the select transistors STD included in the associated string unit SU. The select gate lines SGS0 to SGS3 are associated with the string units SU0 to SU3, respectively. The select gate line SGS is coupled to the gates of the select transistors STS included in the associated block BLK. The word lines WL0 to WL(N−1) are coupled to the control gates of the memory cell transistors MT0 to MT(N−1) included in the associated block BLK.

Note that in the memory cell array 10, the number of string units SU included in each block BLK, and the numbers of select transistors STD and STS included in each NAND string NS, can be designed to freely selected numbers.

In the present specification, a set of memory cell transistors MT coupled to a common word line WL in one string unit SU is referred to as a cell unit CU. In addition, a set of 1-bit data stored in the memory cell transistors MT included in the cell unit CU is referred to as page data. Specifically, a “page” is associated with a set of memory cell transistors MT coupled to a common word line WL in the same block BLK. The cell unit CU can store 2-page data or more, in accordance with the number of bits of the data that each memory cell transistor MT stores. Specifically, the memory controller 2 can manage a storage area of the memory device 1, in units of the cell unit CU composed of the memory cell transistors MT, each of which can store multiple-bit data.

### (2: Circuit Configuration of Data Register 17 and Sense Amplifier Module 18)

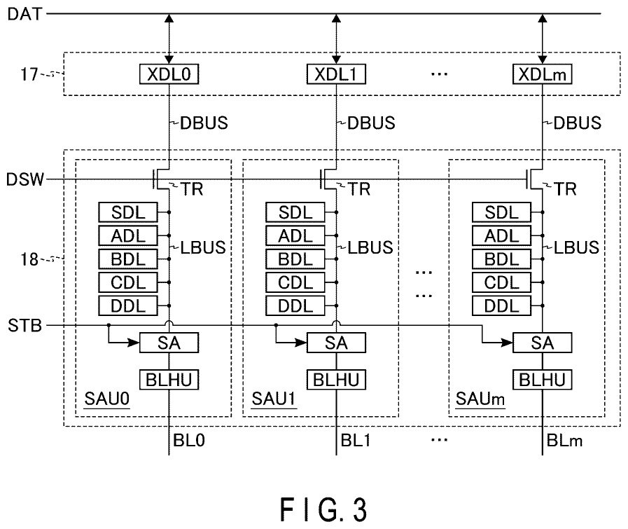

FIG. 3 is a circuit diagram illustrating an example of a circuit configuration of the data register 17 and sense amplifier module 18 included in the memory device 1 according to the first embodiment. As illustrated in FIG. 3, the data register 17 includes latch circuits XDL0 to XDLm. Each of sense amplifier units SAU included in the sense amplifier module 18 includes, for example, a bit line coupling section BLHU, a sense amplifier section SA, buses DBUS and LBUS, latch circuits SDL, ADL, BDL, CDL and DDL, and a transistor TR.

Each latch circuit XDL can temporarily retain (store) data. The latch circuits XDL0 to XDLm are associated with the sense amplifier units SAU0 to SAUm, respectively. Each latch circuit XDL is configured to be capable of transmitting and receiving data to and from the associated sense amplifier unit SAU via the bus DBUS. In addition, each latch circuit XDL is used to input and output the data DAT between the sense amplifier module 18 and the input/output circuit 11. Each latch circuit XDL may be shared by a plurality of sense amplifier units SAU.

The bit line coupling section BLHU is a protection circuit that prevents, for example, a high voltage applied to the channel of the NAND string NS in an erase operation, from being applied to the sense amplifier section SA. The bit line coupling section BLHU includes, for example, a high breakdown voltage transistor. The breakdown voltage of the high breakdown voltage transistor is higher than that of a transistor used in the sense amplifier section SA.

The sense amplifier section SA is a circuit that is used for determining data based on a voltage of the bit line BL, and applying voltage to the bit line BL. Each sense amplifier section SA is coupled to the associated bit line BL via the bit line coupling section BLHU. If a control signal STB is asserted at a time of a read operation, the sense amplifier section SA determines whether data read from the selected memory cell transistor MT is “0” bit data or “1” bit data, based on the voltage of the associated bit line BL.

Each of the latch circuits SDL, ADL, BDL, CDL and DDL can temporarily retain (store) data. The latch circuits SDL, ADL, BDL, CDL and DDL, and the sense amplifier section SA, are configured to be capable of transmitting and receiving data via the bus LBUS. In the write operation of data, the sense amplifier unit SAU controls the bit line BL in accordance with data stored in the latch circuit SDL. For example, if the write operation is completed, data indicating that the write of data to the memory cell transistor MT of the write target is completed is stored in the latch circuit SDL. The other latch circuits are used to temporarily store data of respective bits, for example, at a time when each memory cell transistor MT stores data of 2 bits or more. Note that the number of latch circuits can be freely set. The number of latch circuits is set, for example, in accordance with a data amount (number of bits) that the memory cell transistor MT can store.

The transistor TR controls the transfer of a signal between the associated buses DBUS and LBUS. One end and the other end of the transistor TR of each sense amplifier unit SAU are coupled to the associated buses DBUS and LBUS, respectively. A control signal DSW is input to the gate of the transistor TR of each sense amplifier unit SAU. The control signals STB and DSW are generated by, for example, the sequencer 14.

### (3: Detailed Circuit Configuration of Bit Line Section)

In the memory device 1 according to the first embodiment, the sense amplifier unit SAU and the block BLK are coupled via a plurality of kinds of interconnects functioning as the bit line BL. In other words, the bit line BL is used by being divided into interconnects. The divided bit line BL, for example, is configured to be appropriately branched via a select transistor. In addition, circuits capable of applying higher voltages than the sense amplifier sections SA are coupled to intermediate portions of the bit lines BL. A description below is given by referring to the configuration including these circuits as “bit line section”.

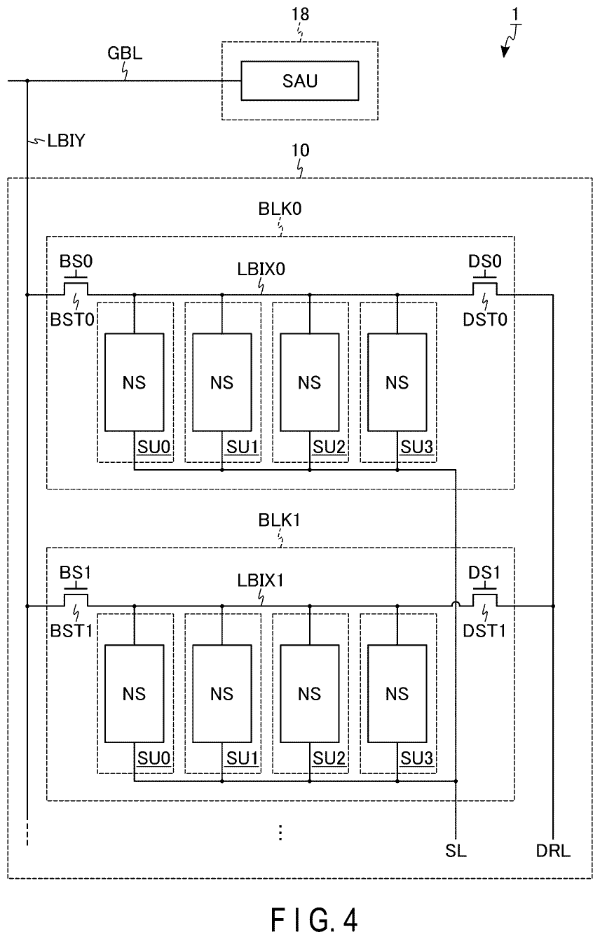

FIG. 4 is a circuit diagram illustrating an example of a circuit configuration of the bit line section included in the memory device 1 according to the first embodiment. FIG. 4 illustrates a bit line BL associated with one sense amplifier unit SAU, and elements and interconnects used to control the bit line BL. As illustrated in FIG. 4, one bit line BL is divided into, for example, a global bit line GBL, a local bit line LBIY, and local bit lines LBIX0 to LBIXn. The local bit lines LBIY and LBIX may be referred to as local block interconnects LBI.

The number of global bit lines GBL corresponds to the number of bit lines BL. For example, the number of local bit lines LBIY corresponds to the number of global bit lines GBL. The number of local bit lines LBIX corresponds to the number of blocks BLK coupled to the associated local bit line LBIY. In the present example, the blocks BLK0 to BLKn are associated with the local bit line LBIY. Each local bit line LBIX is coupled to the NAND strings NS of the string units SU0 to SU3 of the associated block BLK. Note that the number of local bit lines LBIY coupled to the global bit line GBL may be two or more. It suffices that the number of local bit lines LBIX (blocks BLK) coupled to the local bit line LBIY is at least two.

The memory device 1 according to the first embodiment further includes a driver interconnect DRL, and select transistors BST and DST for each block BLK. The driver interconnect DRL is coupled to, for example, the driver circuit 15, and is used for transferring a higher voltage than the sense amplifier section SA. The select transistor BST is a transistor used for selecting the block BLK. The select transistor DST is is a transistor used at a time of transferring the voltage of the driver interconnect DRL to the local bit line LBIX. A set of the driver interconnect DRL and the select transistor DST may be referred to as a driver circuit.

Specifically, the blocks BLK0 to BLKn include select transistors BST0 to BSTn, respectively. In addition, the blocks BLK0 to BLKn include select transistors DST0 to DSTn, respectively. The gates of the select transistors BST0 to BSTn are coupled to select lines BS0 to BSn, respectively. The gates of the select transistors DST0 to DSTn are coupled to select lines DS0 to DSn, respectively. The select line BS can be controlled independently for each block BLK. The select line BS can be controlled independently, for example, for each local bit line LBIX. The voltages applied to the select lines BS and DS are generated by the driver circuit 15, for example, based on the control of the sequencer 14.

One end and the other end of the select transistor BST0 of the block BLK0 are coupled to the local bit lines LBIY and LBIX0, respectively. One end and the other end of the select transistor DST0 of the block BLK0 are coupled to the local bit lines LBIX0 and driver interconnect DRL, respectively. One end and the other end of the select transistor BST1 of the block BLK1 are coupled to the local bit lines LBIY and LBIX1, respectively. One end and the other end of the select transistor DST1 of the block BLK1 are coupled to the local bit lines LBIX1 and driver interconnect DRL, respectively. Similarly, the local bit line LBIX of each block BLK is coupled to the local bit line LBIY via the associated select transistor BST, and is coupled to the driver interconnect DRL via the associated select transistor DST.

### <1-1-3> Configuration of Memory Device 1

Next, a configuration of the memory device 1 according to the first embodiment is described.

In the drawings to be referred to below, a three-dimensional orthogonal coordinate system is used. A Z direction corresponds to a vertical direction to a surface of a semiconductor substrate that serves as a reference. An “up-and-down direction” is defined based on a direction along the Z direction. A forward direction (upward) corresponds to a direction away from the semiconductor substrate serving as the reference. An XY plane (cross section) corresponds to a cross section parallel to each of the X direction and Y direction. A YZ cross section corresponds to a cross section parallel to each of the Y direction and Z direction. An XZ cross section corresponds to a cross section parallel to each of the X direction and Z direction.

### (1: Outline of Configuration of Memory Cell Array 10)

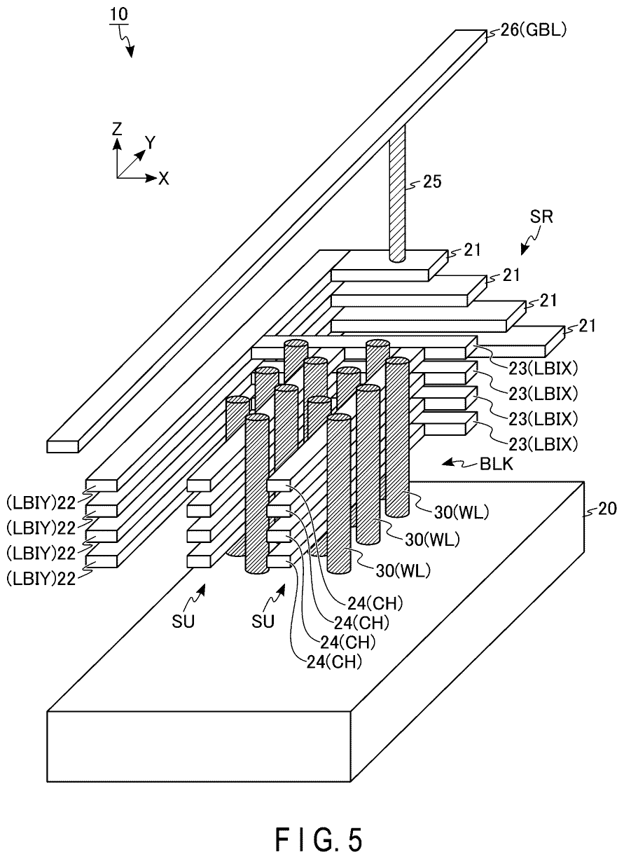

FIG. 5 is a perspective view illustrating an outline of a configuration of the memory device 1 according to the first embodiment. FIG. 5 illustrates an outline of an HCF (Horizontal Channel Flash) in the memory device 1 according to the first embodiment. As illustrated in FIG. 5, the memory device 1 includes, for example, a substrate 20, conductor layers 21, conductive members 22, conductive members 23, semiconductor layers 24, contacts 25, conductor layers 26, and pillars 30. Note that in FIG. 5, one contact 25 and one conductor layer 26 are illustrated in an extracted manner.

The conductor layers 21 are arranged in the Z direction. Mutually neighboring conductor layers 21 in the Z direction are insulated from each other. Each conductor layer 21 includes, for example, a portion extending in the X direction, and a portion (hereinafter referred to as “terrace portion”) that is provided in such a manner as not to overlap an upper-side conductor layer 21. Thereby, the conductor layers 21 include portions that are provided in a staircase fashion. Hereinafter, a region where the conductor layers 21 are provided is referred to as a staircase region SR.

The conductive members 22 are provided at the same heights (layers) as the conductor layers 21. Mutually neighboring conductive members 22 in the Z direction are insulated from each other. Each conductive member 22 includes, for example, a portion extending in the Y direction. Each conductive member 22 is electrically coupled to the conductor layer 21 that is provided at the same height (layer). The conductive member 22 is used as the local bit line LBIY.

The conductive members 23 are provided at the same heights (layers) as the conductor layers 21. Mutually neighboring conductive members 23 in the Z direction are insulated from each other. Each conductive member 23 includes, for example, a portion extending in the X direction. In addition, each conductive member 23 is electrically coupled to the conductive member 22 that is provided at the same height (layer). The conductive member 23 is used as the local bit line LBIX. Note that the number of conductive members 23 provided at the same height corresponds to the number of blocks BLK coupled to the conductive member 22 (local bit line LBIY). The conductive members 23 provided at the same height are arranged in the Y direction. In addition, the conductive members 23 may be electrically coupled to the conductive member 22 from both sides in the X direction. In this case, the blocks BLK can be uniformly arranged on both sides of the conductive member 22 in the X direction.

The semiconductor layers 24 are provided at the same heights (layers) as the conductor layers 21. Mutually neighboring semiconductor layers 24 in the Z direction are insulated from each other. Each semiconductor layer 24 includes, for example, a portion extending in the Y direction. In addition, each semiconductor layer 24 is coupled to the conductive member 23 that is provided at the same height (layer). The semiconductor layer 24 is used as a channel CH of the NAND string NS. Note that the number of semiconductor layers 24 provided at the same height in each block BLK corresponds to the number of string units SU included in one block BLK. The semiconductor layers 24 provided at the same height (layer) are arranged in the X direction. In addition, the semiconductor layers 24 may be electrically coupled to each conductive member 23 from both sides in the Y direction.

Each contact 25 is a conductor provided to extend in the Z direction. The contacts 25 are associated with the conductor layers 21, respectively. Each contact is provided on the terrace portion of the associated conductor layer 21.

The conductor layers 26 are provided in a layer higher than the conductor layers 21. Each conductor layer 26 includes, for example, a portion provided to extend in the Y direction. The conductor layers 26 are arranged, for example, in the X direction (not illustrated). The conductor layers 26 are associated with the conductor layers 21, respectively. Each conductor layer 26 is coupled to the terrace portion of the associated conductor layer 21 via the contact 25. The conductor layer 26 is used as the global bit line GBL.

Each pillar 30 is a conductor provided to extend in the Z direction. The pillars 30 are provided to neighbor the semiconductor layers 24, which are arranged in the Z direction, for each of the string units SU. The pillars 30 are used as the word lines WL. A portion where the pillar 30 and the semiconductor layer 24 neighbor each other (intersect) functions as the memory cell transistor MT.

### (2: Planar Layout of Memory Cell Array 10)

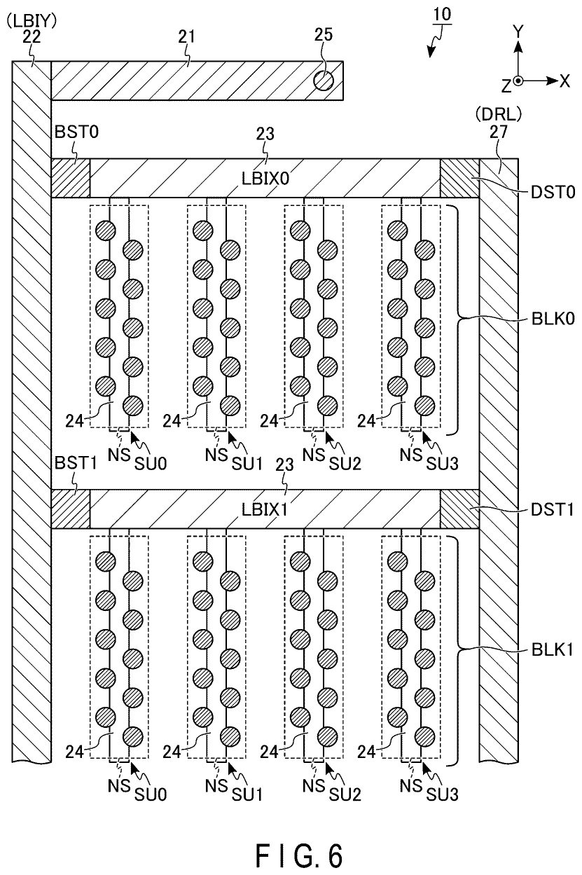

FIG. 6 is a plan view illustrating an example of a planar layout of the memory cell array 10 included in the memory device 1 according to the first embodiment. FIG. 6 illustrates, in an extracted manner, a layer in which the conductive member 22 (local bit line LBIY) is provided in the memory cell array 10. As illustrated in FIG. 6, the memory cell array 10 further includes, for example, a conductor layer 27. The conductor layer 27 includes, for example, a portion extending in the Y direction, and is used as the driver interconnect DRL.

The select transistor BST is provided between the conductive member 22 (local bit line LBIY) and each conductive member 23 (local bit line LBIX). The select transistors BST, which are associated with the same block BLK, overlap each other in the Z direction (not illustrated). The select transistor DST is provided between each conductive member 23 (local bit line LBIX) and the conductor layer 27 (driver interconnect DRL). In the present example, four semiconductor layers 24 are coupled to the conductive member 23 (local bit line LBIX) of each block BLK. The four semiconductor layers 24 coupled to the conductive member 23 of each block BLK correspond to the NAND strings NS of the string units SU0 to SU3.

Note that the structure and arrangement of the select transistors DST and the conductor layer 27 are not limited to the configuration illustrated in FIG. 6. Other elements may be added if an operation similar to the write operation to be described later can be implemented. For example, the illustrated select transistor DST may be structured and controlled in the same manner as the select transistor BST, and a transistor, to which the operation of the select transistor DST to be described later is applied, may be inserted in the current path between the conductor layer 27 of each layer and the driver circuit 15. The arrangement of other structures of the memory cell array 10 may be modified as appropriate.

### (3: Cross-Sectional Configuration of NAND String NS)

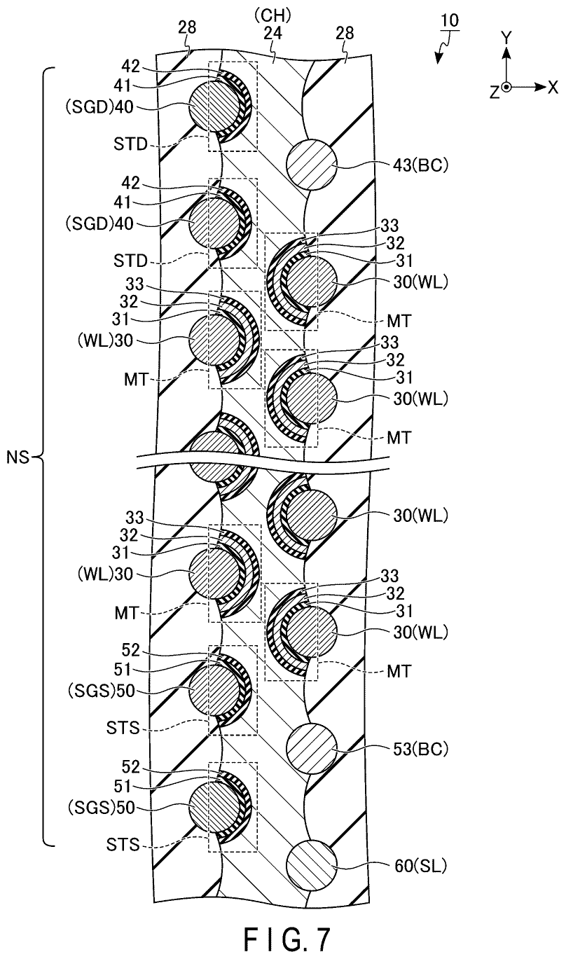

FIG. 7 is a cross-sectional view illustrating an example of a cross-sectional configuration of the NAND string NS included in the memory device 1 according to the first embodiment. FIG. 7 illustrates an XY cross section of one NAND string NS. As illustrated in FIG. 7, the memory cell array 10 further includes, for example, an insulating member 28, pillars 40, 43, 50 and 53 and a pillar 60.

The insulating member 28 is an insulator that is provided, for example, in a portion where the conductive members 22 and 23 are not provided at the height (layer) at which the semiconductor layer 24 is provided. The insulating member 28 is provided, for example, between mutually neighboring semiconductor layers 24 (not illustrated) in the X direction, and separates and insulates mutually neighboring NAND strings NS from each other.

The pillars 30 are arranged, for example, in the Y direction, and are alternately arranged on both sides of the semiconductor layer 24 in the X direction. In other words, the pillars 30 are arranged in a staggered fashion in such a manner as to sandwich the semiconductor layer 24. In addition, each pillar 30 is disposed between the semiconductor layer 24 and the insulating member 28. The pillar 30 and the semiconductor layer 24 are insulated via an insulating film 31, a conductive film 32 and an insulating film 33. The pillar 30 and the insulating film 31, conductive film 32 and insulating film 33, and the semiconductor layer 24 near the pillar 30, function as the memory cell transistor MT. The insulating film 31 functions as a tunnel insulating film. The conductive film 32 functions as a charge storage layer (floating gate). The insulating film 33 functions as a block insulating film.

Each pillar 40 is a conductor provided to extend in the Z direction, and is used as the select gate line SGD. Each pillar 40 is disposed between a portion of the semiconductor layer 24 on the conductive member 23 (local bit line LBIX) side, and the insulating member 28. The pillar 40 and the semiconductor layer 24 are insulated via insulating films 41 and 42. The pillar 40 and the insulating films 41 and 42, and the semiconductor layer 24 near the pillar 40, function as the select transistor STD. The insulating films 41 and 42 function as a gate insulating film. It suffices that each NAND string NS includes at least one set of the pillar 40 and the insulating films 41 and 42. A plurality of sets of the pillar 40 and the insulating films 41 and 42 may be arranged in the Y direction, or may be arranged in the Y direction and alternately arranged on both sides of the semiconductor layer 24 in the X direction. The pillar 43 is a semiconductor provided to extend in the Z direction. As the pillar 43, for example, silicon doped with P-type impurities, such as boron (B), is used. The pillar 43 is disposed near the select transistor STD, and is in contact with the semiconductor layer 24. The pillar 43 is used as a body contact BC of the select transistor STD.

Each pillar 50 is a conductor provided to extend in the Z direction, and is used as the select gate line SGS. Each pillar 50 is disposed between a portion of the semiconductor layer 24 on the source line SL side, and the insulating member 28. The pillar 50 and the semiconductor layer 24 are insulated via insulating films 51 and 52. The pillar 50 and the insulating films 51 and 52, and the semiconductor layer 24 near the pillar 50, function as the select transistor STS. It suffices that each NAND string NS includes at least one set of the pillar 50 and the insulating films 51 and 52. A plurality of sets of the pillar 50 and the insulating films 51 and 52 may be arranged in the Y direction, or may be arranged in the Y direction and alternately arranged on both sides of the semiconductor layer 24 in the X direction. The pillar 53 is a semiconductor provided to extend in the Z direction. As the pillar 53, for example, silicon doped with P-type impurities, such as boron (B), is used. The pillar 53 is disposed near the select transistor STS, and is in contact with the semiconductor layer 24. The pillar 53 is used as a body contact BC for the select transistor STS.

The pillar 60 is a conductor provided to extend in the Z direction, and is used as the source line SL. The pillar 60 is disposed between an end portion of the semiconductor layer 24 on the opposite side to the conductive member 23 (local bit line LBIX), and the insulating member 28. The pillar 60 and the semiconductor layer 24 are electrically coupled. As the pillar 60, for example, silicon doped with N-type impurities such as phosphorus (P) is used.

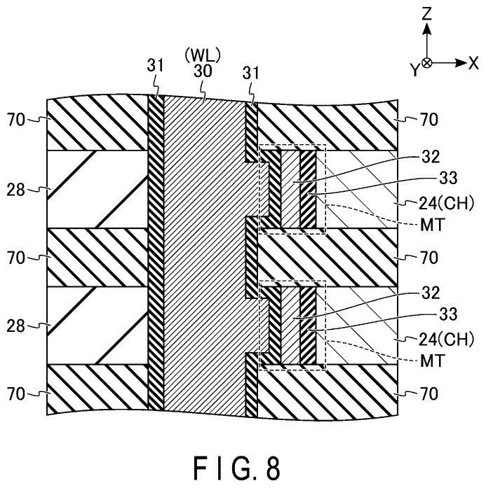

FIG. 8 is a cross-sectional view illustrating an example of a cross-sectional configuration of the memory cell transistor MT included in the memory device 1 according to the first embodiment. FIG. 8 illustrates an XZ cross section including two memory cell transistors MT that neighbor each other in the Z direction. As illustrated in FIG. 8, the memory cell array 10 further includes, for example, a plurality of insulator layers 70. The insulator layers 70 are disposed by being arranged in the Z direction. Each insulator layer 70 separates and insulates mutually neighboring interconnect layers in the Z direction (layers including the conductor layers 21 and conductive members 22 and 23). The pillar 30 (word line WL) is provided to penetrate the insulator layers 70 arranged in the Z direction. The insulating film 31 is provided on a side surface of the pillar 30. The insulating film 31 of each memory cell transistor MT is continuously provided between mutually neighboring memory cell transistors MT in the Z direction. At the same height (layer) as the semiconductor layer 24, a step can be formed in that portion of the pillar 30 and insulating film 31, which neighbors the semiconductor layer 24 of each interconnect layer. The conductive film 32 and insulating film 33 of each memory cell transistor MT are separated between the mutually neighboring memory cell transistors MT in the Z direction.

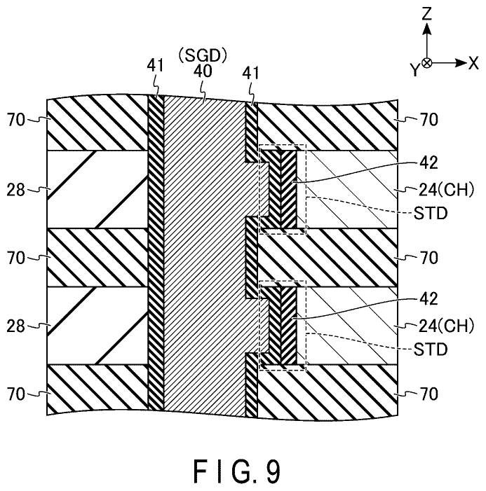

FIG. 9 is a cross-sectional view illustrating an example of a cross-sectional configuration of the select transistor STD included in the memory device 1 according to the first embodiment. As illustrated in FIG. 9, the pillar 40 (select gate line SGD) is provided to penetrate the insulator layers 70 arranged in the Z direction. The insulating film 41 is provided on a side surface of the pillar 40. The insulating film 41 of each select transistor STD is continuously provided between mutually neighboring select transistors STD in the Z direction. At the same height (layer) as the semiconductor layer 24, a step can be formed in that portion of the pillar 40 and insulating film 41, which neighbors the semiconductor layer 24 of each interconnect layer. The insulating film 42 of each select transistor STD is separated between the mutually neighboring select transistors STD in the Z direction. Note that the cross-sectional configuration of the select transistor STS is similar to, for example, a configuration in which the pillar 40 and insulating films 41 and 42 in the cross-sectional configuration of the select transistor STD are replaced with the pillar 50 and insulating films 51 and 52.

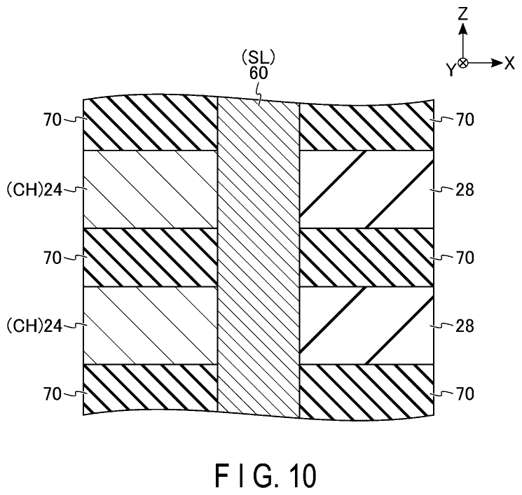

FIG. 10 is a cross-sectional view illustrating an example of a cross-sectional configuration of the source line SL included in the memory device 1 according to the first embodiment. As illustrated in FIG. 10, the pillar 60 (source line SL) is provided to penetrate the insulator layers 70 arranged in the Z direction. A side surface of the pillar 60 is coupled to the semiconductor layers 24 stacked in the Z direction.

### (4: Cross-Sectional Configuration of Memory Cell Array 10)

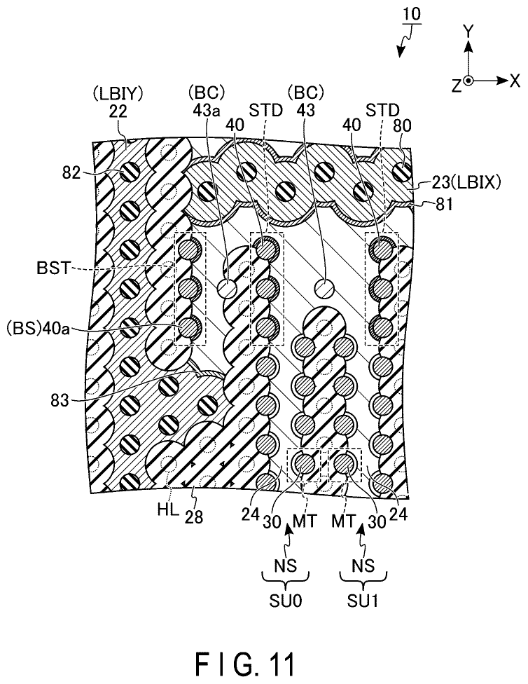

FIG. 11 is a cross-sectional view illustrating an example of a cross-sectional configuration of the memory cell array 10 included in the memory device 1 according to the first embodiment. FIG. 11 illustrates an XY cross section of that region of the memory cell array 10, which includes the local bit lines LBIX and LBIY. As illustrated in FIG. 11, the memory cell array 10 further includes, for example, insulating members 80 and 82, semiconductor layers 81 and 83, and pillars 40a and 43a.

The insulating member 80 is a columnar member provided to extend in the Z direction. In the memory cell array 10, a plurality of insulating members 80 are arranged in the X direction. In addition, the periphery of each insulating member 80 is covered with the conductive member 23 (local bit line LBIX). The conductive member 23 is formed in such a manner that, for example, a plurality of holes corresponding to the insulating members 80 and penetrating the insulator layers 70 are formed, and then a portion of the semiconductor layer 24 of each interconnect layer is removed via the holes, and a conductor is filled in the space from which the semiconductor layer 24 is removed. In addition, the conductive members 23 provided on the peripheries of two mutually neighboring insulating members 80 are electrically coupled. Thus, the conductive member 23 can include a portion along the outer periphery of each insulating member 80. In addition, the conductive member 23 can include a boundary between two mutually neighboring insulating members 80.

The semiconductor layer 81 is provided between the conductive member 23 and the semiconductor layer 24. The semiconductor layer 81 includes, for example, silicon doped with N-type impurities such as phosphorus (P). In each interconnect layer in the block BLK, the conductive member 23 and the NAND strings NS of each string unit SU are electrically coupled via the semiconductor layer 81.

The insulating member 82 is a columnar member provided to extend in the Z direction. In the memory cell array 10, a plurality of insulating members 82 are arranged in the Y direction. In addition, the periphery of each insulating member 82 is covered with the conductive member 22 (local bit line LBIY). The conductive member 22 is formed in such a manner that, for example, a plurality of holes corresponding to the insulating members 82 and penetrating the insulator layers 70 are formed, and then a portion of the semiconductor layer 24 of each interconnect layer is removed via the holes, and a conductor is filled in the space from which the semiconductor layer 24 is removed. In addition, the conductive members 22 provided on the peripheries of two mutually neighboring insulating members 82 are electrically coupled. Thus, the conductive member 22 can include a portion along the outer periphery of each insulating member 82. In addition, the conductive member 22 can include a boundary between two mutually neighboring insulating members 82.

The semiconductor layer 83 is provided between the conductive member 22 and the semiconductor layer 24. The semiconductor layer 83 includes, for example, silicon doped with N-type impurities such as phosphorus (P). In each interconnect layer in the block BLK, the conductive member 22 and the conductive member 23 (local bit line LBIX) are electrically coupled via the semiconductor layer 83 and 24.

Each pillar 40a is a conductor provided to extend in the Z direction, and is used as the select line BS. Each pillar 40a is disposed, for example, between the semiconductor layer 24, which is provided between the conductive members 22 and 23, and the insulating member 28. For example, like the select transistor STD, a gate insulating film is provided between each pillar 40a and the semiconductor layer 24. The pillar 40a and gate insulating film, and the semiconductor layer 24 near the pillar 40a, function as the select transistor BST. It suffices that each block BLK includes at least one set of the pillar 40a and the gate insulating film for each interconnect layer. A plurality of sets of the pillar 40a and the gate insulating film may be arranged in the Y direction, or may be arranged in the Y direction and alternately arranged on both sides of the semiconductor layer 24 in the X direction. The pillar 43a is a semiconductor provided to extend in the Z direction. As the pillar 43a, for example, silicon doped with P-type impurities, such as boron (B), is used. The pillar 43a is disposed near the select transistor BST, and is in contact with the semiconductor layer 24. The pillar 43a is used as a body contact BC of the select transistor BST.

Note that in the present example, after the stacked structure of the semiconductor layers 24 and insulator layers 70 is formed, and before the conductive members 22 and 23 are formed, a plurality of holes HL penetrating the insulating layers 70 are formed. Thereafter, a portion of the semiconductor layer 24 of each interconnect layer is removed via the holes HL, and the insulating member 28 is buried. Thus, each of the conductive members 22 and 23 can include a portion along the outer periphery of each hole HL.

Note that in the memory device 1, two mutually neighboring string units SU may be provided symmetrically in the X direction. In this case, the body contact BC (pillar 43) of the select transistor STD can be shared by two mutually neighboring string units SU. In this case, one body contact BC is provided for each two string units SU.

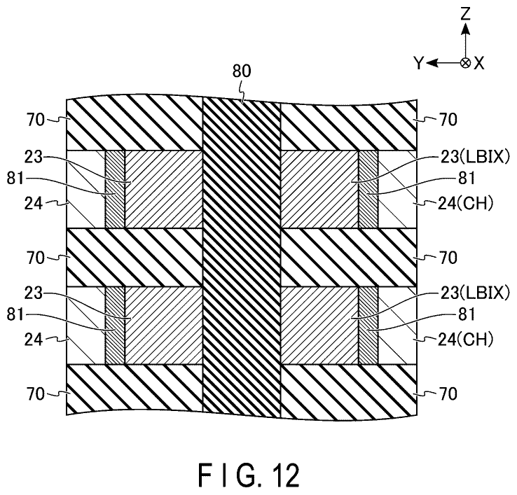

FIG. 12 is a cross-sectional view illustrating an example of a cross-sectional configuration of the local bit line LBIX included in the memory device 1 according to the first embodiment. FIG. 12 illustrates a YZ cross section including two mutually neighboring local bit lines LBIX in the Z direction. As illustrated in FIG. 12, the insulating member 80 is provided to penetrate the insulating layers 70 arranged in the Z direction. A side surface of the insulating member 80 is in contact with the conductive member 23 (local bit line LBIX) of each interconnect layer. In each interconnect layer, the conductive member 23 is coupled to the semiconductor layer 24 via the semiconductor layer 81. Two mutually neighboring conductive members 23 in the Z direction are separated and insulated via the insulating layer 70.

### <1-1-4> Threshold Voltage Distribution of Memory Cell Transistors MT

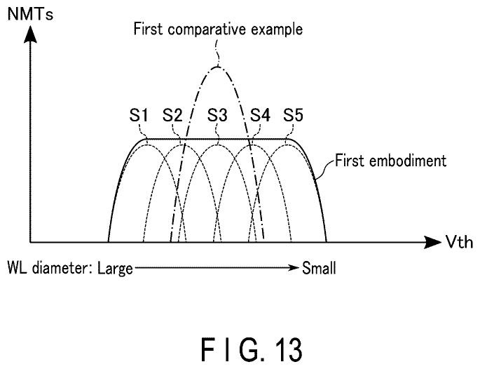

FIG. 13 is a diagram illustrating an example of a threshold voltage distribution of the memory cell transistors MT included in the memory device 1 according to the first embodiment. In a graph illustrated in FIG. 13, the abscissa axis indicates threshold voltages (Vth) of the memory cell transistors MT, and the ordinate axis indicates the number (NMTs) of memory cell transistors MT. A first comparative example that is illustrated indicates a threshold voltage distribution of memory cell transistors MT, in a case where predetermined data is written to a 3D-NAND having such a configuration that a channel extends in a direction perpendicular to the substrate. As illustrated in FIG. 13, in the HCF (Horizontal Channel Flash) such as the memory device 1 according to the first embodiment, in a case of writing predetermined data to the NAND string NS, write characteristics vary from position to position. Thus, a variance in threshold voltage of memory cell transistors MT may occur in accordance with the positions thereof.

For example, in the memory device 1, the pillar 30 (word line WL) or the like can have a taper shape or a bowing shape. Specifically, the pillar 30 or the like can have a diameter that varies in accordance with the height from the bottom portion thereof. In a program operation in which an identical program voltage is utilized, an increase amount of a threshold voltage in a case where the diameter of the word line WL is large becomes smaller, and an increase amount of a threshold voltage in a case where the diameter of the word line WL is small becomes greater. Thus, the threshold voltage distribution of memory cell transistors MT in the memory device 1 according to the first embodiment is, for example, a combination of states S1 to S5, in a case where predetermined data is written. For example, as in the first comparative example, in a case where the channel is formed in a direction perpendicular to the substrate, the variance in threshold distribution in accordance with the diameter of the pillar can be suppressed. Thus, in the memory device 1, it is required to suppress the variance in threshold voltage of the memory cell transistors MT in accordance with the diameter of the pillar 30.

### <1-2> Write Operation

Next, a write operation of the memory device 1 according to the first embodiment is described. In the write operation, the memory device 1 repeatedly executes a set of a program operation of increasing the threshold voltage of the memory cell transistor MT, and a verify read operation. Based on the result of the verify read operation, the memory device 1 can confirm whether the threshold voltage of the memory cell transistor MT of the write target has reached a target state. In addition, based on the result of the verify read operation, the memory device 1 sets the bit line BL to be a program-target or a program-inhibit in a later program operation.

Note that in the program operation, a charge process of the bit line BL is executed before applying a program voltage to the memory cell transistor MT of the write target. In the charge process, the select transistor STD coupled to the bit line BL of the program-target is controlled and set in the ON state. At this time, the channel voltage of the NAND string NS coupled to the bit line BL of the program-target is based on the voltage applied to the bit line BL. On the other hand, in the charge process, the select transistor STD coupled to the bit line BL of the program-inhibit is controlled and set in the OFF state. At this time, the channel voltage of the NAND string NS coupled to the bit line BL of the program-inhibit is boosted based on the voltage applied to each word line WL.

In addition, in the write operation, low-level voltages are applied to the select transistors BST, STD and STS of an unselected block BLK. The select line BS is shared by the select transistors BST in the block BLK. Thus, in the selected block BLK, the same voltage is applied to the select transistor BST coupled to the bit line BL of the program-target, and to the select transistor BST coupled to the bit line BL of the program-inhibit. On the other hand, in the selected block BLK, different voltages are applied to the select transistor DST coupled to the bit line BL of the program-target, and to the select transistor DST coupled to the bit line BL of the program-inhibit.

### <1-2-1>Bit Line BL of Program-Target

Hereinafter, a description is given of an example of the operation of each structure associated with the bit line BL of the program-target in the write operation of the memory device 1 according to the first embodiment. Note that in the description below of the first embodiment, it is assumed that the voltage applied to the global bit line GBL is applied to the select transistor BST via the local bit line LBIY.

### (1: Time of Charge)

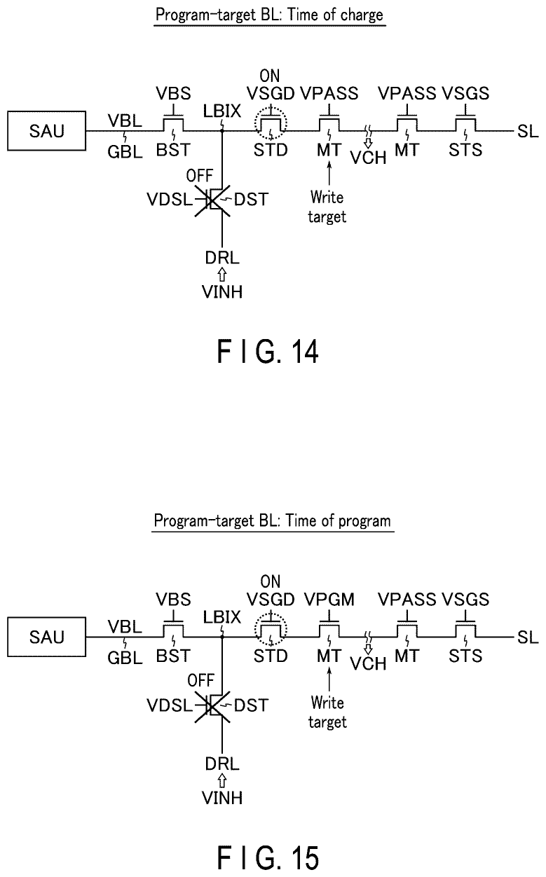

FIG. 14 is a diagram illustrating an example of an operation of the NAND string coupled to the bit line BL of the program-target (program-target BL) at a charge time of a write operation of the memory device 1 according to the first embodiment. As illustrated in FIG. 14, at the charge time, the sequencer 14 applies a voltage VSGD to the select transistor STD (select gate line SGD), applies a voltage VSGS to the select transistor STS (select gate line SGS), applies a voltage VBS to the select transistor BST (select line BS), applies a voltage VDSL to the select transistor DST (select line DS), and applies a voltage VINH to the driver interconnect DRL. The sense amplifier unit SAU (sense amplifier section SA) applies a voltage VBL to the global bit line GBL.

The voltages VSGD and VSGS are voltages corresponding to a high level. The voltage VSGD is a voltage higher than the voltage VBS. The voltage VBS is a voltage higher than the voltage VBL. In the bit line BL of the program-target, the sense amplifier unit SAU can control and set, for example, the voltage VBL to a voltage corresponding to a position of the memory cell transistor MT or data to be written. The voltage VDSL is a voltage corresponding to a low level. The voltage VINH is a voltage higher than the voltage VBS.

The select transistor DST, to which the voltage VDSL is applied, enters the OFF state. Thus, the voltage VINH, which is applied to the driver interconnect DRL, is not transferred to the local bit line LBIX via the select transistor DST. The select transistor BST, to which the voltage VBS is applied, enters the ON state. Thereby, the voltage VBL applied to the global bit line GBL is transferred to the local bit line LBIX via the select transistor BST. In addition, the select transistor STD enters the ON state, based on a voltage difference between the voltage VSGD applied to the gate and the voltage of the local bit line LBIX. Thereby, the channel voltage VCH of the NAND string NS becomes a voltage based on the voltage VBL.

Thereafter, a program pass voltage VPASS is applied to each memory cell transistor MT (word line WL) of the NAND string NS. The program pass voltage VPASS is a voltage higher than the voltage VSGD. At this time, in the NAND string NS coupled to the bit line BL of the program-target, since the select transistor STD is in the ON state, the channel voltage is kept at the voltage based on the voltage VBL.

### (2: Time of Program)

FIG. 15 is a diagram illustrating an example of an operation of the NAND string NS coupled to the bit line BL of the program-target (program target BL) at a program time of a write operation of the memory device 1 according to the first embodiment. As illustrated in FIG. 15, the sequencer 14 applies a program voltage VPGM to the memory cell transistor MT (word line WL) of the write target at the program time. The program voltage VPGM is a voltage higher than the program pass voltage VPASS. If the program voltage VPGM is applied, electrons are injected in the charge storage layer of the memory cell transistor MT, based on a voltage difference between the control gate and the channel CH. Thus, the amount of increase of the threshold voltage of the memory cell transistor MT can be controlled by the channel voltage VCH of the NAND string NS being adjusted within such a range that the select transistor STD does not enter the OFF state. Note that the program voltage VPGM is stepped up, for example, each time the program operation is repeated.

### <1-2-2> Bit Line BL of Program-Inhibit

Hereinafter, a description is given of an example of the operation of each structure associated with the bit line BL of the program-inhibit in the write operation of the memory device 1 according to the first embodiment, mainly with respect to the points different from the case of the bit line BL of the program-target described with reference to FIG. 14 and FIG. 15.

### (1: Time of Charge)

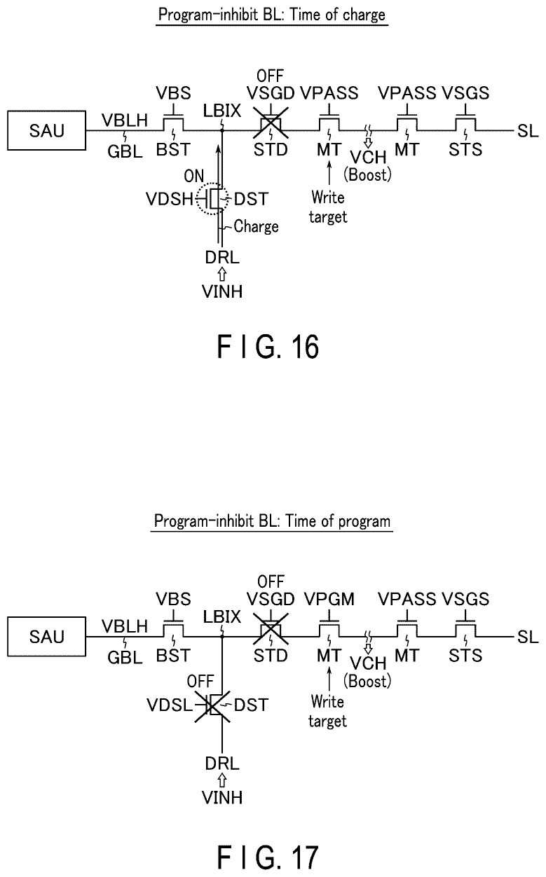

FIG. 16 is a diagram illustrating an example of an operation of the NAND string NS coupled to the bit line BL of the program-inhibit (program-inhibit BL) at a charge time of a write operation of the memory device 1 according to the first embodiment. As illustrated in FIG. 16, at the charge time, the sequencer 14 applies a voltage VDSH to the select transistor DST (select line DS). The sense amplifier unit SAU (sense amplifier section SA) applies, for example, a voltage VBLH to the global bit line GBL. The voltage VDSH is a voltage corresponding to a high level. The voltage VBLH is a voltage that is higher than the voltage VBL and is lower than the voltage VBS.

The select transistor DST, to which the voltage VDSH is applied, enters the ON state. Thus, the voltage VINH applied to the driver interconnect DRL is transferred to the local bit line LBIX via the select transistor DST. Then, the voltage of the local bit line LBIX becomes higher than the voltage VBS, and the select transistor BST enters the OFF state. In addition, the select transistor STD enters the OFF state in accordance with the increase of voltage of the local bit line LBIX. Thereby, the channel CH of the NAND string NS enters a floating state. Thereafter, if the program pass voltage VPASS is applied to each memory cell transistor MT (word line WL) of the NAND string NS, the channel voltage VCH is boosted.

Note that in the bit line BL of the program-inhibit of the first embodiment, the voltage applied to the global bit line GBL by the sense amplifier unit SAU can be varied within such a range that the select transistor BST can keep the OFF state. The sequencer 14 may apply a low-level voltage to the select transistor BST (select line BS) during a period during which the local bit line LBIX is charged via the select transistor DST. In this case, the sequencer 14 applies the voltage VBS to the select transistor BST after the charging of the local bit line LBIX is completed.

### (2: Time of Program)

FIG. 17 is a diagram illustrating an example of an operation of the NAND string NS coupled to the bit line BL of the program-inhibit (program-inhibit BL) at a program time of a write operation of the memory device 1 according to the first embodiment. As illustrated in FIG. 17, at the program time, the program voltage VPGM is applied to the memory cell transistor MT (word line WL) of the write target. If the program voltage VPGM is applied, since the channel voltage VCH of the NAND string NS coupled to the bit line BL of the program-inhibit is boosted, the injection of electrons in the charge storage layer of the write target is suppressed.

### <1-3> Advantageous Effects of First Embodiment

According to the memory device 1 of the above-described first embodiment, the reliability of the memory device 1 can be improved. Hereinafter, the details of the advantageous effects of the first embodiment are described using a second comparative example. The second comparative example corresponds to a case where the select transistor DST and the driver interconnect DRL are omitted from the memory device 1 according to the first embodiment.

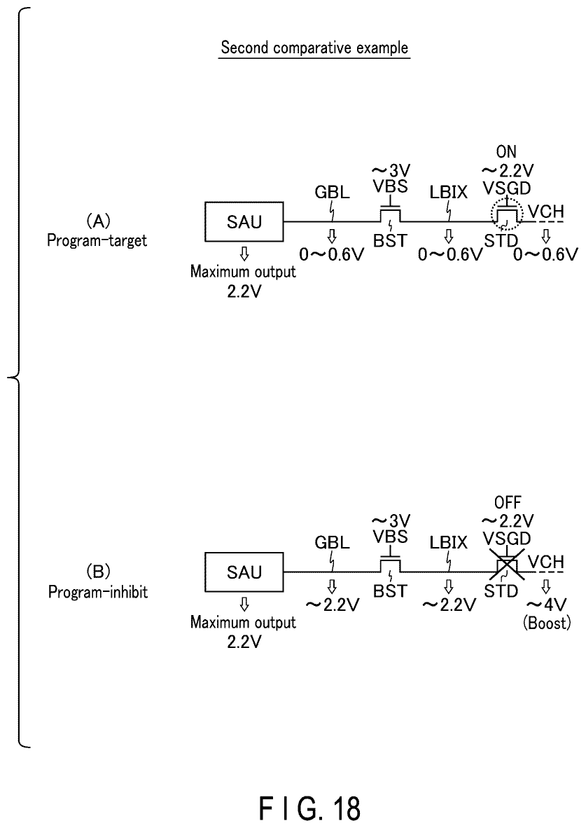

FIG. 18 is a diagram illustrating a concrete example of an operation of the NAND string NS at a time of a write operation in the second comparative example. Parts (A) and (B) of FIG. 18 illustrate concrete examples of voltages of the global bit line GBL, select transistor BST (select line BS), local bit line LBIX, select transistor STD (select gate line SGD), and channel CH in the cases of the program-target and the program-inhibit. In the second comparative example, the maximum output voltage of the sense amplifier unit SAU is set at 2.2 V. In addition, in the write operation, in the selected block BLK, the voltage VBS is controlled and set at ~3 V, and the voltage VSGD is controlled and set at ~2.2 V.

In addition, as illustrated in part (A) of FIG. 18, the sense amplifier unit SAU can control the voltage in the range of 0~0.6 V for the global bit line GBL corresponding to the bit line BL of the program-target. This range corresponds to a range of voltages that can keep the ON state of the select transistor STD, to the gate of which the voltage of ~2.2 V is applied, and can transfer the voltage of the global bit line GBL to the channel CH. The voltage of the local bit line LBIX corresponding to the bit line BL of the program-target becomes 0~0.6 V, based on the voltage of the global bit line GBL, and the channel voltage VCH similarly becomes 0~0.6 V.

Besides, as illustrated in part (B) of FIG. 18, the sense amplifier unit SAU applies a voltage of 2.2 V to the global bit line GBL corresponding to the bit line BL of the program-inhibit. This voltage corresponds to a voltage capable of setting the select transistor STD in the OFF state. Specifically, the voltage of the local bit line LBIX corresponding to the bit line BL of the program-inhibit becomes ~2.2 V, based on the voltage of the global bit line GBL. In addition, since the voltage of the local bit line LBIX and the voltage of the select gate line SGD become substantially equal, the select transistor STD enters the OFF state. As a result, since the select transistor STD is set in the OFF state, the channel voltage VCH is boosted up to, for example, ~4 V.

In this manner, in the second comparative example, the select transistor STD is controlled and set in the OFF state, based on the voltage VBLH applied to the bit line BL of the program-inhibit at the time of the write operation, and the voltage VSGD applied to the select gate line SGD. Thus, the voltage of the select gate line SGD cannot be raised to the maximum output voltage or more of the sense amplifier unit SAU. In addition, due to the potential (voltage) loss in the select transistor STD, the transfer potential (voltage) is limited to ~0.6 V.

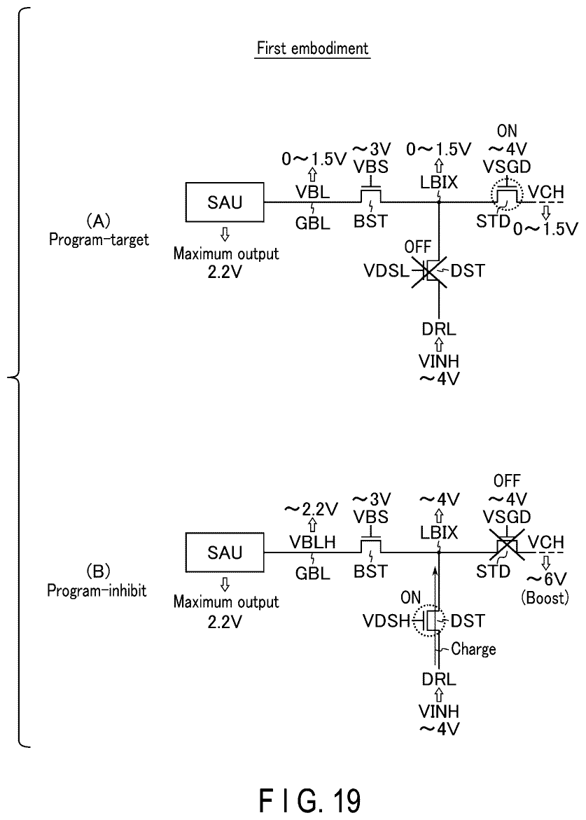

FIG. 19 is a diagram illustrating a concrete example of an operation of the NAND string NS at a time of a write operation in the first embodiment. Parts (A) and (B) of FIG. 19 illustrate concrete examples of voltages of the global bit line GBL, select transistor BST (select line BS), local bit line LBIX, select transistor DST (select line DS), select transistor STD (select gate line SGD), and channel CH in the cases of the program-target and the program-inhibit. In the present example, the maximum output voltage of the sense amplifier unit SAU is set at 2.2 V, like the second comparative example. In addition, in the write operation, in the selected block BLK, the voltage VBS is controlled and set at ~3 V, and the voltage VSGD is controlled and set at ~4 V, which is higher than in the second comparative example.

In addition, as illustrated in part (A) of FIG. 19, in the memory device 1 according to the first embodiment, the select transistor DST associated with the bit line BL of the program-target is controlled and set in the OFF state. Furthermore, the sense amplifier unit SAU of the first embodiment can control the voltage for the global bit line GBL corresponding to the bit line BL of the program-target in a wider range of 0~1.5 V than in the second comparative example. This range corresponds to a range of voltages that can keep the ON state of the select transistor STD, to the gate of which the voltage of ~4 V is applied, and can transfer the voltage of the global bit line GBL to the channel CH. In the present example, the voltage of the local bit line LBIX corresponding to the bit line BL of the program-target becomes 0~1.5 V, based on the voltage of the global bit line GBL, and the channel voltage VCH similarly becomes 0~1.5 V.

Besides, as illustrated in part (B) of FIG. 19, in the memory device 1 according to the first embodiment, the select transistor DST associated with the bit line BL of the program-inhibit is controlled and set in the ON state. Thereby, the voltage VINH (for example, ~4 V) of the driver interconnect DRL is transferred to the local bit line LBIX via the select transistor DST. In addition, the voltage of the local bit line LBIX corresponding to the bit line BL of the program-inhibit becomes ~4 V, based on the voltage of the driver interconnect DRL. Then, since the voltage of the local bit line LBIX and the voltage of the select gate line SGD become substantially equal, the select transistor STD enters the OFF state. As a result, since the select transistor STD is set in the OFF state, the channel voltage VCH is boosted up to, for example, ~6 V. Note that in the present example, the sense amplifier unit SAU of the first embodiment applies a voltage of, for example, 2.2 V to the global bit line GBL corresponding to the bit line of the program-inhibit. The voltage applied to the global bit line GBL corresponding to the bit line of the program-inhibit is not particularly limited.

In this manner, in the first embodiment, in the case of the program-inhibit at the time of the write operation, the select transistor STD is controlled and set in the OFF state, based on the voltage VINH applied via the select transistor DST, and the voltage VSGD applied to the select gate line SGD. Thus, in the memory device 1 according to the first embodiment, the voltage of the select gate line SGD can be raised up to the maximum output voltage or more of the sense amplifier unit SAU. Accordingly, the potential (voltage) loss in the select transistor STD can be suppressed and the transfer potential (voltage) can be extended to ~1.5 V. Specifically, in the memory device 1 according to the first embodiment, even in the case where the maximum output voltage of the sense amplifier unit SAU is similar to that in the second comparative example, the voltage applied to the bit line BL of the program-target can be controlled in a wider range than in the second comparative example.

Thereby, in the write operation, the memory device 1 according to the first embodiment can increase the range of the operation voltage of the voltage VBL that is applied to the bit line BL of the program-target by the sense amplifier unit SAU, and can increase variations of the operation.

For example, the memory device 1 according to the first embodiment can decrease the difference in write characteristics by varying the height of the voltage applied to the bit line BL of the program-target in accordance with the position of the memory cell transistor MT. As a result, the memory device 1 according to the first embodiment can hold down a difference in the amount of increase of threshold voltages corresponding to the positions of memory cell transistors MT, and can make narrower the threshold voltage distribution of memory cell transistors MT than in the second comparative example. Furthermore, in accordance with the narrowing of the threshold voltage distribution, the memory device 1 can suppress the occurrence of a read error. In addition, the memory device 1 according to the first embodiment can simultaneously write data of multiple levels by varying the height of the voltage applied to the bit line BL of the program-target in accordance with the data of the write target. In this case, the memory device 1 can improve the speed of the write operation.

As has been described above, the memory device 1 according to the first embodiment can improve the performance of the memory device 1.

### <2> Second Embodiment

A memory device 1A according to a second embodiment relates to a configuration that can implement the same operation as in the first embodiment, in a case where a plurality of local bit lines LBIY are coupled to one global bit line GBL. Hereinafter, the memory device 1A according to the second embodiment is described with respect to different points from the first embodiment.

### <2-1> Configuration

To begin with, a configuration of the memory device 1A according to the second embodiment is described.

### <2-1-1> Circuit Configuration of Memory Device 1A

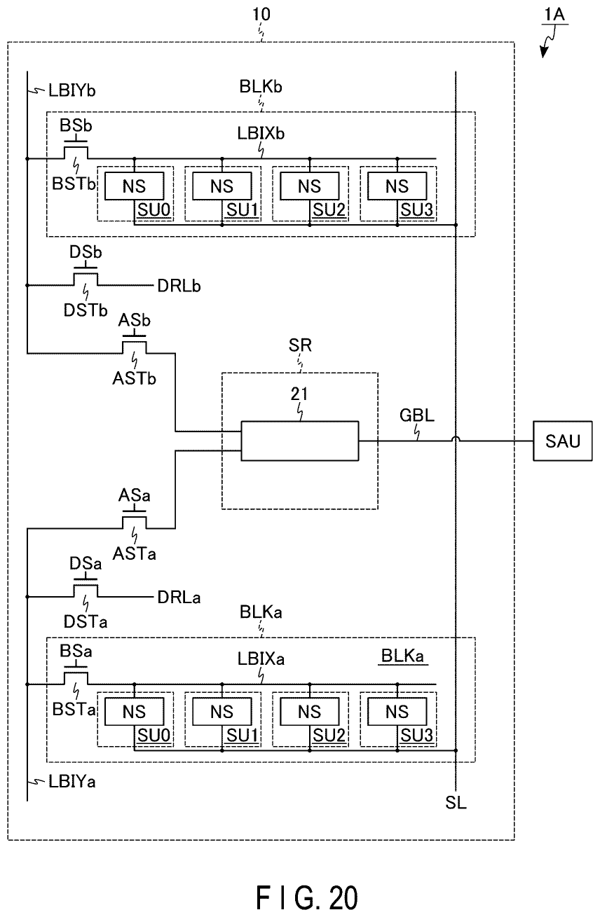

FIG. 20 is a circuit diagram illustrating an example of a circuit configuration of the memory device 1A according to the second embodiment. As illustrated in FIG. 20, a memory cell array 10 of the memory device 1A includes two local bit lines LBIYa and LBIYb provided for one global bit line GBL, and includes select transistors ASTa and ASTb. Hereinafter, “a” is added to the end of the reference sign of a structure associated with the local bit line LBIYa, and “b” is added to the end of the reference sign of a structure associated with the local bit line LBIYb.

The local bit line LBIYa is coupled to the global bit line GBL via the select transistor ASTa and the conductor layer 21. Specifically, one end and the other end of the select transistor ASTa are coupled to the local bit line LBIYa and the global bit line GBL, respectively. The local bit line LBIYb is coupled to the global bit line GBL via the select transistor ASTb and the conductor layer 21. Specifically, one end and the other end of the select transistor ASTb are coupled to the local bit line LBIYb and the global bit line GBL, respectively. The select transistors ASTa and ASTb are coupled to select lines ASa and ASb, respectively. The voltages applied to the select lines ASa and ASb are generated by the driver circuit 15, for example, based on the control of the sequencer 14.

At least one block BLKa is coupled to the local bit line LBIYa. A local bit line LBIXa of each block BLKa is coupled to the local bit line LBIYa via a select transistor BSTa. The select transistor BSTa is coupled to a select line BSa. Four NAND strings NS corresponding to the string units SU0 to SU3 are coupled between the local bit line LBIXa and the source line SL. A driver interconnect DRLa is coupled to the local bit line LBIYa via a select transistor DSTa. The gate of the select transistor DSTa is coupled to a select line DSa.

At least one block BLKb is coupled to the local bit line LBIYb. A local bit line LBIXb of each block BLKb is coupled to the local bit line LBIYb via a select transistor BSTb. The select transistor BSTb is coupled to a select line BSb. Four NAND strings NS corresponding to the string units SU0 to SU3 are coupled between the local bit line LBIXb and the source line SL. A driver interconnect DRLb is coupled to the local bit line LBIYb via a select transistor DSTb. The gate of the select transistor DSTb is coupled to a select line DSb.

As has been described above, the memory device 1A according to the second embodiment is provided with the select transistors AST for selecting the local bit line LBIY coupled to one global bit line GBL. In addition, in the memory device 1A, unlike the first embodiment, the select transistor DST is coupled to not the local bit line LBIX, but the local bit line LBIY. Note that the number of local bit lines LBIY coupled to the global bit line GBL may be three or more. The voltages applied to the driver interconnects DRLa and DRLb may be controlled independently, or may be controlled batchwise.

### <2-1-2> Configuration of Memory Device 1A

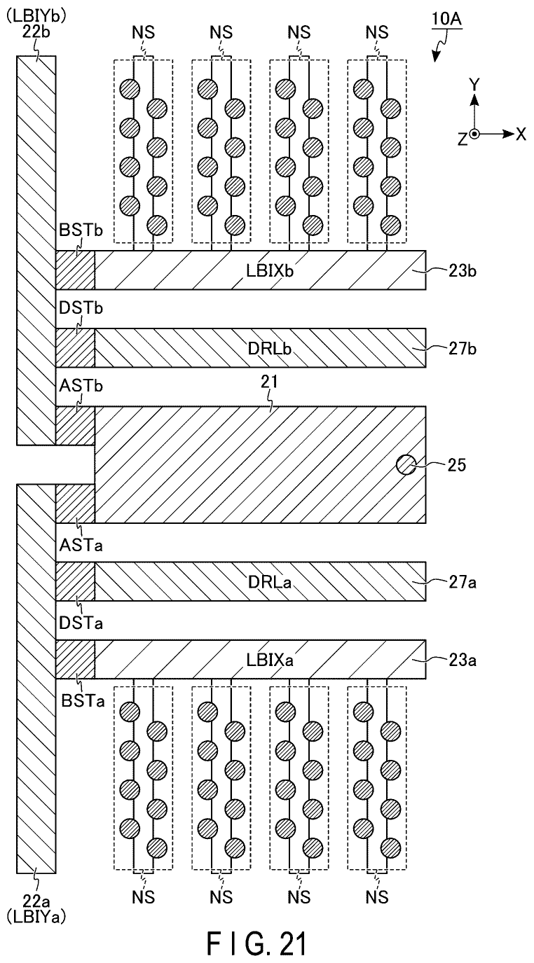

FIG. 21 is a plan view illustrating an example of a planar layout of a memory cell array 10A included in the memory device 1A according to the second embodiment. FIG. 21 illustrates, in an extracted manner, a layer in which a conductive member 22a (local bit line LBIYa) and a conductive member 22b (local bit line LBIYb) are provided in the memory cell array 10A. As illustrated in FIG. 21, the memory cell array 10A of the second embodiment further includes, for example, conductor layers 27a and 27b. The conductor layers 27a and 27b are used as driver interconnects DRLa and DRLb, respectively.

The select transistor BSTa is provided between the conductive member 22a (local bit line LBIYa) and a conductive member 23a (local bit line LBIXa). The select transistor DSTa is provided between the conductive member 23a (local bit line LBIXa) and the conductor layer 27a (driver interconnect DRLa). The select transistor BSTb is provided between the conductive member 22b (local bit line LBIYb) and a conductive member 23b (local bit line LBIXb). The select transistor DSTb is provided between the conductive member 23b (local bit line LBIXb) and the conductor layer 27b (driver interconnect DRLb).

Note that the structure and arrangement of the select transistors DSTa and DSTb and the conductor layers 27a and 27b are not limited to the configuration illustrated in FIG. 21. Other elements may be added if an operation similar to the write operation to be described later can be implemented. The arrangement of other structures of the memory cell array 10A may be modified as appropriate. The other structures of the memory device 1A according to the second embodiment are similar to the structures of the memory device 1 according to the first embodiment.

### <2-2> Write Operation

Next, the write operation of the memory device 1A according to the second embodiment is described by taking, by way of example, a case where the block BLKa is selected and the block BLKb is not selected.

### <2-2-1> Bit Line BL of Program-Target

Hereinafter, a description is given of an example of the operation of each structure associated with the bit line BL of the program-target in the write operation of the memory device 1A according to the second embodiment, mainly with respect to the points different from the write operation of the memory device 1 according to the first embodiment.

### (1: Time of Charge)

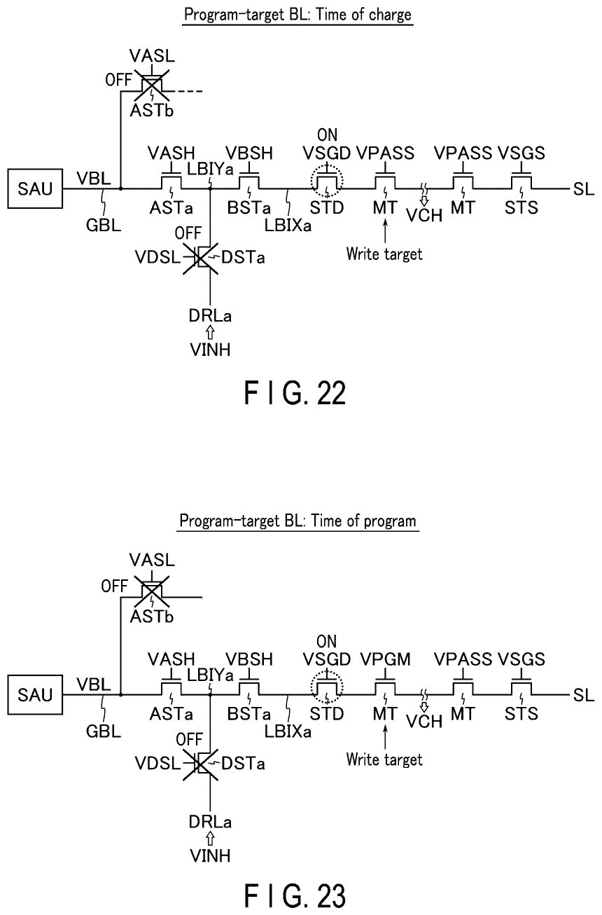

FIG. 22 is a diagram illustrating an example of an operation of the NAND string NS coupled to the bit line BL of the program-target (program-target BL) at a charge time of a write operation of the memory device 1A according to the second embodiment. As illustrated in FIG. 22, at the charge time, the sequencer 14 applies a voltage VBSH to the select transistor BSTa (select line BSa), applies a voltage VDSL to the select transistor DSTa (select line DS), applies a voltage VASH to the select transistor ASTa (select line ASa), applies a voltage VASL to the select transistor ASTb (select line ASb), and applies a voltage VINH to the driver interconnect DRLa. The sense amplifier unit SAU applies a voltage VBL to the global bit line GBL. The voltage VASL is a voltage corresponding to a low level. The voltage VASH is a voltage that corresponds to a high level and is higher than the voltage VBL. The voltage VBSH is, for example, a voltage higher than the voltage VASH.

The select transistor ASTb, to which the voltage VASL is applied, enters the OFF state. The select transistor ASTa, to which the voltage VASH is applied, enters the ON state. The select transistor DSTa, to which the voltage VDSL is applied, enters the OFF state. Thus, the voltage VINH applied to the driver interconnect DRLa is not transferred to the local bit line LBIXa via the select transistor DSTa. The select transistor BSTa, to which the voltage VBSH is applied, enters the ON state. Thereby, the voltage VBL applied to the global bit line GBL is transferred to the local bit line LBIXa via the select transistors ASTa and BSTa. In addition, the select transistor STD enters the ON state, based on a difference in voltage between the voltage VSGD applied to the gate, and the local bit line LBIXa. Thereby, the channel voltage VCH of the NAND string NS becomes a voltage based on the voltage VBL.

### (2: Time of Program)

FIG. 23 is a diagram illustrating an example of an operation of the NAND string NS coupled to the bit line BL of the program-target (program-target BL) at a program time of a write operation of the memory device 1A according to the second embodiment. As illustrated in FIG. 23, at the program time, the sequencer 14 applies a program voltage VPGM to the memory cell transistor MT (word line WL) of the write target. If the program voltage VPGM is applied, electrons are injected in the charge storage layer of the memory transistor MT, based on a difference in voltage between the control gate and the channel CH. Thus, like the first embodiment, the amount of increase of the threshold voltage of the memory cell transistor MT can be controlled by the channel voltage VCH of the NAND string NS being adjusted within such a range that the select transistor STD does not enter the OFF state.

### <2-2-2> Bit Line BL of Program-Inhibit

Hereinafter, a description is given of an example of the operation of each structure associated with the bit line BL of the program-inhibit in the write operation of the memory device 1A according to the second embodiment, mainly with respect to the points different from the case of the bit line BL of the program-target described with reference to FIG. 22 and FIG. 23.

### (1: Time of Charge)

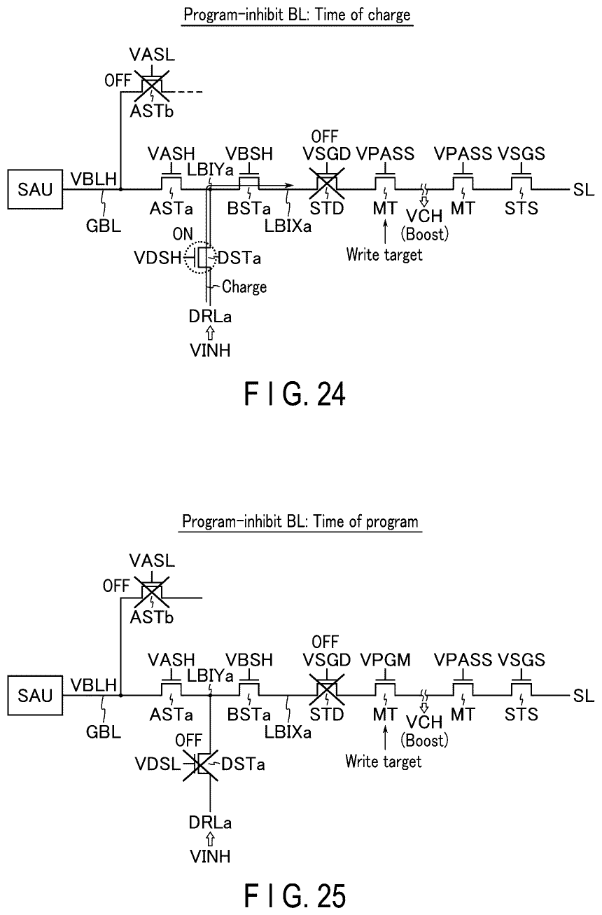

FIG. 24 is a diagram illustrating an example of an operation of the NAND string NS coupled to the bit line BL of the program-inhibit (program-inhibit BL) at a charge time of a write operation of the memory device 1A according to the second embodiment. As illustrated in FIG. 24, at the program time, the sequencer 14 applies a voltage VDSH to the select transistor DSTa (select line DSa). The sense amplifier unit SAU applies, for example, a voltage VBLH to the global bit line GBL. In the second embodiment, the voltage VBLH is a voltage that is higher than the voltage VBL and is lower than each of the voltages VASH and VBSH.

The select transistor DSTa, to which the voltage VDSH is applied, enters the ON state. Thus, the voltage VINH applied to the driver interconnect DRL is transferred to the local bit line LBIYa via the select transistor DSTa. Then, the voltage of the local bit line LBIYa becomes higher than the voltage VASH, and the select transistor ASTa enters the OFF state. In addition, the select transistor BSTa, to which the voltage VBSH is applied, enters the ON state. Then, the voltage of the local bit line LBIYa is transferred to the local bit line LBIXa via the select transistor BSTa. Then, the select transistor STD enters the OFF state in accordance with the increase of voltage of the local bit line LBIXa. Thereby, the channel CH of the NAND string NS enters the floating state. Thereafter, if the program pass voltage VPASS is applied to each memory cell transistor MT (word line WL) of the NAND string NS, the channel voltage VCH is boosted.

Note that in the bit line BL of the program-inhibit of the second embodiment, the voltage applied to the global bit line GBL by the sense amplifier unit SAU can be varied within such a range that the select transistor ASTa is in the OFF state.

### (2: Time of Program)

FIG. 25 is a diagram illustrating an example of an operation of the NAND string NS coupled to the bit line BL of the program-inhibit (program-inhibit BL) at a program time of a write operation of the memory device 1A according to the second embodiment. As illustrated in FIG. 25, at the program time, the program voltage VPGM is applied to the memory cell transistor MT (word line WL) of the write target. If the program voltage VPGM is applied, since the channel voltage VCH of the NAND string NS coupled to the bit line BL of the program-inhibit is boosted, the injection of electrons in the charge storage layer of the write target is suppressed, like the first embodiment.

The other operations of the memory device 1A according to the second embodiment are the same as the operations of the memory device 1 according to the first embodiment.

### <2-3> Advantageous Effects of Second Embodiment

According to the memory device 1A of the second embodiment, the same advantageous effects as in the first embodiment can be obtained. Note that the positions of the select transistors DSTa and DSTb described in the second embodiment may be changed as in the first embodiment. Specifically, the select transistors DSTa and DSTb may be coupled to the local bit lines LBIXa and LBIXb, respectively. In this case, too, the same advantageous effects as in the first embodiment can be obtained by the select transistors DSTa and DSTb being controlled in the same manner as in the first embodiment.

### <3> Third Embodiment

A memory device 1B according to a third embodiment achieves the same advantageous effects as in the first embodiment by utilizing a circuit formed in the staircase region SR. Hereinafter, the memory device 1B according to the third embodiment is described with respect to different points from the first and second embodiments.

### <3-1> Configuration

Next, a configuration of the memory device 1B according to the third embodiment is described.

### <3-1-1> Circuit Configuration of Memory Device 1B

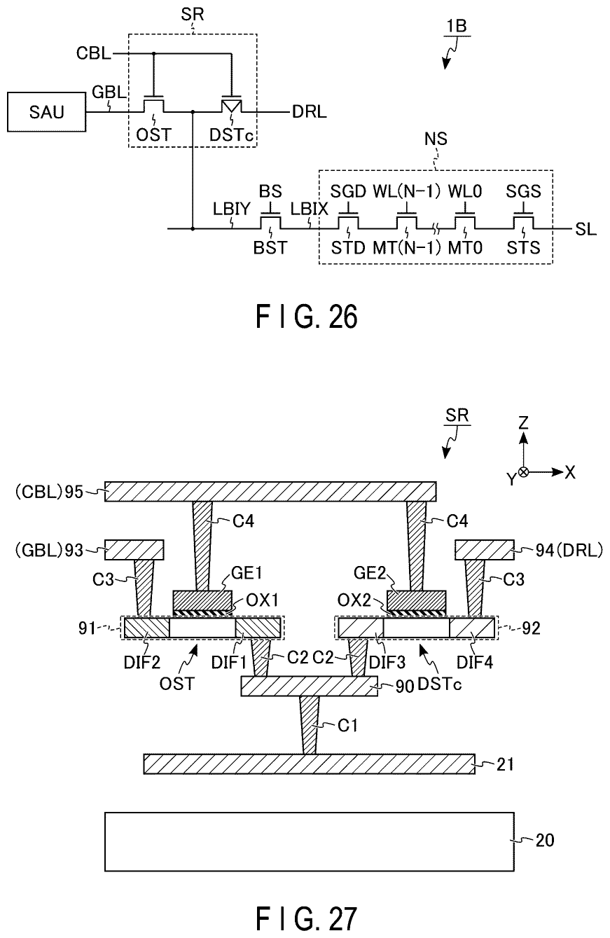

FIG. 26 is a circuit diagram illustrating an example of a circuit configuration of the memory device 1B according to the third embodiment. As illustrated in FIG. 26, the memory device 1B according to the third embodiment has such a configuration that select transistors OST and DSTc and a control bit line CBL are added for each global bit line GBL in the memory device 1 according to the first embodiment.

The select transistors OST and DSTc are disposed in the staircase region SR. The select transistors OST and DSTc are a n-channel transistor and a p-channel transistor, respectively. One end and the other end of the select transistor OST are coupled to the global bit line GBL and the local bit line LBIY, respectively. One end and the other end of the select transistor DSTc are coupled to the driver interconnect DRL and the local bit line LBIY, respectively. The control bit line CBL is coupled to the gates of the select transistors OST and DSTc. Each control bit line CBL, for example, can be independently controlled by the sequencer 14.

### <3-1-2> Configuration of Memory Device 1B

FIG. 27 is a cross-sectional view illustrating an example of a cross-sectional configuration of the staircase region SR of the memory cell array 10 included in the memory device 1B according to the third embodiment. As illustrated in FIG. 27, in the staircase region SR, the memory cell array 10 includes, for example, a conductor layer 90, semiconductor layers 91 and 92, conductor layers 93, 94 and 95, and contacts C1 to C4.

The conductor layer 90 is provided above the conductor layer 21. The conductor layer 90 is coupled to the conductor layer 21 via the contact C1. The semiconductor layers 91 and 92 are provided in an interconnect layer above the conductor layer 90. The conductor layers 93 and 94 are provided in an interconnect layer above the semiconductor layer 91. The conductor layer 95 is provided in an interconnect layer above the conductor layers 93 and 94.

The semiconductor layer 91 includes P-type impurities. In addition, the semiconductor layer 91 includes diffusion regions DIF1 and DIF2 of N-type impurities. A gate electrode GE1 is provided via a gate insulating film OX1 between the diffusion regions DIF1 and DIF2 and on the semiconductor layer 91. The semiconductor layer 91, gate insulating film OX1 and gate electrode GE1 function as the select transistor OST. The diffusion region DIF1 of the semiconductor layer 91 is coupled to the conductor layer 90 via the contact C2. The diffusion region DIF2 of the semiconductor layer 91 is coupled to the conductor layer 93 via the contact C3. The conductor layer 93 functions as the global bit line GBL.

The semiconductor layer 92 includes N-type impurities. In addition, the semiconductor layer 92 includes diffusion regions DIF3 and DIF4 of P-type impurities. A gate electrode GE2 is provided via a gate insulating film OX2 between the diffusion regions DIF3 and DIF4 and on the semiconductor layer 92. The semiconductor layer 92, gate insulating film OX2 and gate electrode GE2 function as the select transistor DSTc. The diffusion region DIF3 of the semiconductor layer 92 is coupled to the conductor layer 90 via the contact C2. The diffusion region DIF4 of the semiconductor layer 92 is coupled to the conductor layer 94 via the contact C3. The conductor layer 94 functions as the driver interconnect DRL.

The conductor layer 95 is coupled to the gate electrode GE1 of the select transistor OST and to the gate electrode GE2 of the select transistor DSTc via the two contacts C4. The conductor layer 95 functions as the control bit line CBL.

The other structures of the memory device 1B according to the third embodiment are the same as the structures of the memory device 1 according to the first embodiment.

### <3-2> Write Operation

Next, the write operation of the memory device 1B according to the third embodiment is described.

### <3-2-1> Bit Line BL of Program-Target

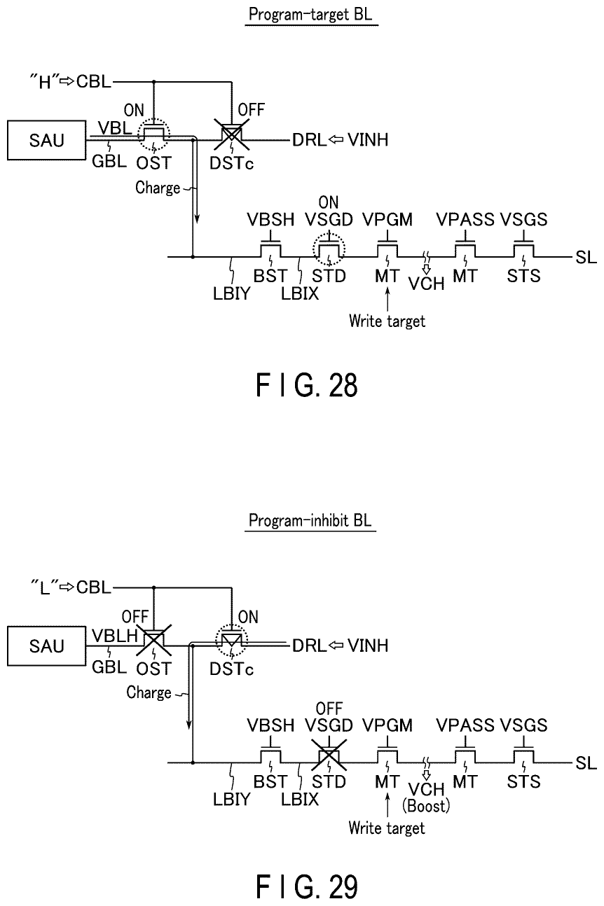

FIG. 28 is a diagram illustrating an example of an operation of the NAND string NS coupled to the bit line BL of the program-target (program-target BL) at a program time of a write operation of the memory device 1B according to the third embodiment. As illustrated in FIG. 28, at the charge time, the sequencer 14 applies a voltage VSGD to the select transistor STD (select gate line SGD), applies a voltage VSGS to the select transistor STS (select gate line SGS), applies a voltage VBS to the select transistor BST (select line BS), applies a voltage VDSL to the select transistor DST (select line DS), applies a voltage VINH to the driver interconnect DRL, and applies a high-level voltage (“H”) to the control bit line CBL. The sense amplifier unit SAU (sense amplifier section SA) applies a voltage VBL to the global bit line GBL.

The select transistors OST and DSTc, to which the high-level voltage is applied, enter the ON state and the OFF state, respectively. Thus, the voltage VBL applied to the global bit line GBL is transferred to the local bit line LBIY, and the local bit line LBIY is charged. On the other hand, the voltage VINH applied to the driver interconnect DRL is not transferred to the local bit line LBIY via the select transistor DSTc. In addition, the select transistor BST, to which the voltage VBSH is applied, enters the ON state. Thereby, the voltage of the local bit line LBIY is transferred to the local bit line LBIX via the select transistor BST. Then, the select transistor STD enters the ON state, based on a difference in voltage between the voltage VSGD applied to the gate, and the local bit line LBIX. Thereby, the channel voltage VCH of the NAND string NS becomes a voltage based on the voltage VBL.

Thereafter, the program pass voltage VPASS is applied to each memory cell transistor MT (word line WL) of the NAND string NS. At this time, in the NAND string NS coupled to the bit line BL of the program-target, since the select transistor STD is in the ON state, the channel voltage is kept at the voltage based on the voltage VBL.

At the program time, if the program voltage VPGM is applied to the memory cell transistor MT (word line WL) of the write target, electrons are injected in the charge storage layer of the memory cell transistor MT, based on a voltage difference between the control gate and the channel CH. Thus, like the first embodiment, the amount of increase of the threshold voltage of the memory cell transistor MT can be controlled by the channel voltage VCH of the NAND string NS being adjusted within such a range that the select transistor STD does not enter the OFF state.

### <3-2-2> Bit Line BL of Program-Inhibit

FIG. 29 is a diagram illustrating an example of an operation of the NAND string NS coupled to the bit line BL of the program-inhibit (program-inhibit BL) at a program time of a write operation of the memory device 1B according to the third embodiment. As illustrated in FIG. 29, at the charge time, the sequencer 14 applies a low-level voltage (“L”) to the control bit line CBL. In addition, the sense amplifier unit SAU (sense amplifier section SA) applies, for example, a voltage VBLH to the global bit line GBL.

The select transistors OST and DSTc, to which the low-level voltage is applied, enter the OFF state and the ON state, respectively. Thus, the voltage VINH applied to the driver interconnect DRL is transferred to the local bit line LBIY, and the local bit line LBIY is charged. On the other hand, the voltage VBLH applied to the global bit line GBL is not transferred to the local bit line LBIY via the select transistor OST. In addition, the select transistor BST, to which the voltage VBSH is applied, enters the ON state. Thereby, the voltage of the local bit line LBIY is transferred to the local bit line LBIX via the select transistor BST. Then, the select transistor STD enters the OFF state in accordance with the increase of voltage of the local bit line LBIX. Thereby, the channel CH of the NAND string NS enters a floating state. Thereafter, if the program pass voltage VPASS is applied to each memory cell transistor MT (word line WL) of the NAND string string NS, the channel voltage VCH is boosted.

At the program time, if the program voltage VPGM is applied to the memory cell transistor MT (word line WL) of the write target, electrons are injected in the charge storage layer of the memory cell transistor MT, based on a voltage difference between the control gate and the channel CH. Thus, like the first embodiment, the amount of increase of the threshold voltage of the memory cell transistor MT can be controlled by the channel voltage VCH of the NAND string NS being adjusted within such a range that the select transistor STD does not enter the OFF state.

At the program time, if the program voltage VPGM is applied to the memory cell transistor MT (word line WL) of the write target, since the channel voltage VCH of the NAND string NS coupled to the bit line BL of the program-inhibit is boosted, the injection of electrons in the charge storage layer of the write target is suppressed, like the first embodiment.

The other operations of the memory device 1B according to the third embodiment are the same as the operations of the memory device 1 according to the first embodiment.

### <3-3> Advantageous Effects of Third Embodiment

According to the memory device 1B of the third embodiment, the same advantageous effects as in the first embodiment can be obtained. Furthermore, in the memory device 1B according to the third embodiment, the number of elements used for controlling the bit line BL can be made smaller than in the first embodiment. As a result, the memory device 1B according to the third embodiment can make smaller the circuit area than in the first embodiment, and can hold down the manufacturing cost of the memory device 1B.

### <4> Fourth Embodiment

In a memory device 1C according to a fourth embodiment, the circuit formed in the staircase region SR in the memory device 1B according to the third embodiment is controlled based on the voltage of the global bit line GBL. Hereinafter, the memory device 1C according to the fourth embodiment is described with respect to different points from the memory device 1B according to the third embodiment.

### <4-1> Configuration

To begin with, a configuration of the memory device 1C according to the fourth embodiment is described.

### <4-1-1> Circuit Configuration of Memory Device 1C

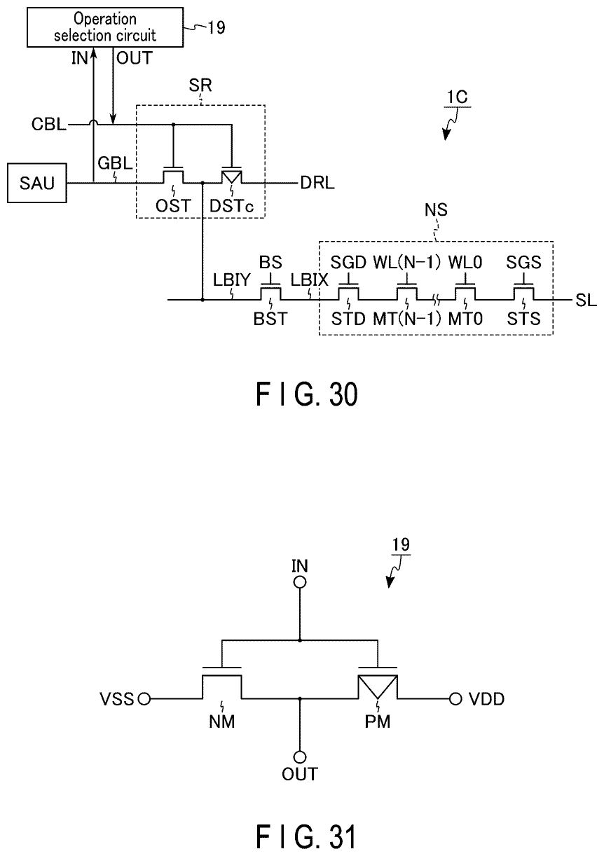

FIG. 30 is a circuit diagram illustrating an example of a circuit configuration of the memory device 1C according to the fourth embodiment. As illustrated in FIG. 30, the memory device 1C according to the fourth embodiment has such a configuration that an operation selection circuit 19 is added for each global bit line GBL in the memory device 1B according to the third embodiment. The operation selection circuit 19 includes an input terminal IN coupled to the global bit line GBL, and an output terminal OUT coupled to the control bit line CBL. The operation selection circuit 19 is configured to control and set the voltage of the output terminal OUT at a low level or at a high level, based on the voltage of the associated global bit line GBL.

### <4-1-2> Configuration of Operation Selection Circuit 19

FIG. 31 is a circuit diagram illustrating an example of a circuit configuration of the operation selection circuit 19 included in the memory device 1C according to the fourth embodiment. As illustrated in FIG. 31, the operation selection circuit 19 includes transistors NM and PM. The transistors NM and PM are an n-channel-type transistor and a p-channel-type transistor, respectively. For example, as a voltage corresponding to the low level, a ground voltage VSS is applied to one end of the transistor NM. For example, as a voltage corresponding to the high level, a power supply voltage VDD is applied to one end of the transistor PM. The other ends of the transistors NM and PM are coupled to the output terminal OUT. The gates of the transistors NM and PM are coupled to the input terminal IN.

In the operation selection circuit 19, in a case where the voltage of the input terminal IN is lower than a predetermined voltage, the transistors NM and PM enter the OFF state and the ON state, respectively, and output a high-level voltage (for example, power supply voltage VDD) to the output terminal OUT. In addition, in the operation selection circuit 19, in a case where the voltage of the input terminal IN is equal to or higher than the predetermined voltage, the transistors NM and PM enter the ON state and the OFF state, respectively, and output a low-level voltage (for example, ground voltage VSS) to the output terminal OUT.

Note that the circuit configuration of the operation selection circuit 19 may be other circuit configuration, if similar operations can be implemented. The operation selection circuit 19 may be configured to output a high-level voltage (for example, power supply voltage VDD) to the output terminal OUT, in a case where the voltage of the input terminal IN is equal to a predetermined threshold. Other structures of the memory device 1C according to the fourth embodiment are the same as the structures of the memory device 1B according to the third embodiment.

### <4-2> Write Operation

Next, the write operation of the memory device 1C according to the fourth embodiment is described.

### <4-2-1> Bit Line BL of Program-Target

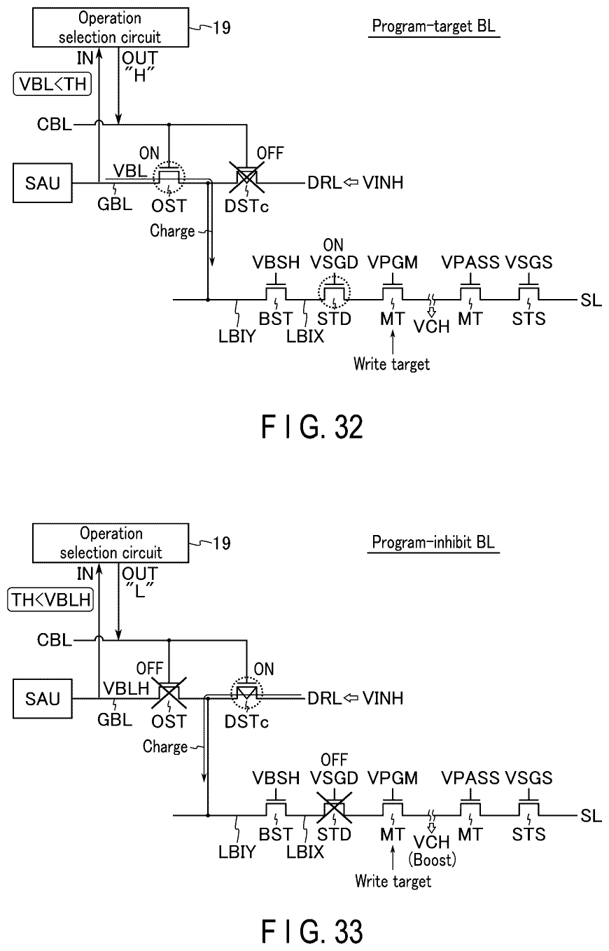

FIG. 32 is a diagram illustrating an example of an operation of the NAND string NS coupled to the bit line BL of the program-target (program-target BL) at a program time of a write operation of the memory device 1C according to the fourth embodiment. As illustrated in FIG. 32, the sense amplifier unit SAU (sense amplifier section SA) applies a voltage VBL to the bit line BL of the program-target. The voltage VBL is a voltage lower than a predetermined threshold TH that is set for the operation selection circuit 19. Thus, based on the voltage of the input terminal IN being the VBL, the operation selection circuit 19 applies the high-level voltage to the control bit line CBL. In addition, the select transistors OST and DSTc, to which the high-level voltage is applied, enter the ON state and the OFF state, respectively. The other operations of the NAND string NS, and the like, coupled to the bit line BL of the program-target are the same as the operations of the third embodiment described with reference to FIG. 28.

### <4-2-2> Bit Line BL of Program-Inhibit

FIG. 33 is a diagram illustrating an example of an operation of the NAND string NS coupled to the bit line BL of the program-inhibit (program-inhibit BL) at a program time of a write operation of the memory device 1C according to the fourth embodiment. As illustrated in FIG. 33, the sense amplifier unit SAU (sense amplifier section SA) applies a voltage VBLH to the bit line BL of the program-inhibit. The voltage VBLH is a voltage higher than the predetermined threshold TH that is set for the operation selection circuit 19. Thus, based on the voltage of the input terminal IN being the VBLH, the operation selection circuit 19 applies the low-level voltage to the control bit line CBL. In addition, the select transistors OST and DSTc, to which the low-level voltage is applied, enter the OFF state and the ON state, respectively. The other operations of the NAND string NS, and the like, coupled to the bit line BL of the program-inhibit are the same as the operations of the third embodiment described with reference to FIG. 29.

The other operations of the memory device 1C according to the fourth embodiment are the same as the operations of the memory device 1B according to the third embodiment.

### <4-3> Advantageous Effects of Fourth Embodiment

According to the memory device 1C of the fourth embodiment, the same advantageous effects as in the third embodiment can be obtained. Furthermore, in the memory device 1C according to the fourth embodiment, the area of arrangement of the control bit line CBL and the circuit area used for controlling the control bit line CBL can be made smaller than in the third embodiment. As a result, the memory device 1C according to the fourth embodiment can make smaller the circuit area than in the third embodiment, and can hold down the manufacturing cost of the memory device 1C.

### <5> Modifications, Etc.

The concepts described in the above-described embodiments can be combined as appropriate. For example, the configuration described in the second embodiment, in which a plurality of local bit lines LBIY are coupled to one global bit line GBL via select transistors AST, may be combined with any one of the first, third and fourth embodiments. In the above-described embodiments, the circuit configuration, planar layout and cross-sectional configuration of the memory device 1 can be modified as appropriate. The numbers of interconnect layers and contacts included in the memory device 1 can be changed as appropriate, in accordance with circuit designs. Each pillar and each contact may have a taper shape, an inverse taper shape, or a bowing shape. Each interconnect of stacked interconnects may include a metal oxide film around a conductor such as tungsten. The conductor layers that, together with insulator layers, are alternately stacked in the stacked interconnects may be regarded as having a structure including such metal oxide films.

In the above-described embodiments, the high-level voltage is a voltage that sets an n-channel-type transistor, to the gate of which this high-level voltage is applied, in the ON state, and that sets a p-channel-type transistor, to the gate of which this high-level voltage is applied, in the OFF state. The low-level voltage is a voltage that sets an n-channel-type transistor, to the gate of which this low-level voltage is applied, in the OFF state, and that sets a p-channel-type transistor, to the gate of which this low-level voltage is applied, in the ON state. Each of the high level and the low level may be referred to as a logical level. In the present specification, the application of voltage to a word line WL corresponds to the application of voltage to the word line WL by the driver circuit 15 via the row decoder module 16. The application of voltage to other interconnects, like the word line WL, corresponds to the application of voltage by the driver circuit 15 via the row decoder module 16. The voltage of each interconnect may be estimated based on the voltage of a signal line that couples the driver circuit 15 and the row decoder module 16.

In the present specification, the term “couple” refers to electrical coupling, and does not exclude, for example, interposition of another element therebetween. The phrase “electrically coupled” may mean electrical coupling via an insulator, if an operation is possible in the same manner as electrical coupling. The term “region” may be regarded as a structure that the substrate 20 includes. For example, in a case where the substrate 20 is defined as including the staircase region SR, the staircase region SR is related to a region above the substrate 20. The term “height” corresponds to, for example, a distance in the Z direction between a structure of a measurement target and the substrate 20. As a reference of “height”, a structure other than the substrate 20 may be used. The term “top (plan) view” corresponds to, for example, viewing of a surface of the substrate 20 from a vertical direction of the substrate 20. The term “conductivity type” corresponds to a P type or an N type.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a first bit line;
a first select transistor, one end of the first select transistor being coupled to the first bit line;
a second bit line coupled to the other end of the first select transistor;
a string including a second select transistor and a memory cell transistor, the second select transistor being coupled to the second bit line;
a word line coupled to the memory cell transistor;
a sense amplifier coupled to the first bit line; and
a driver circuit coupled to the first bit line or the second bit line,
wherein in a case where the memory cell transistor is set to be a program-inhibit in a write operation, the sense amplifier applies a first voltage to the first bit line, and the driver circuit applies a second voltage higher than the first voltage to the second bit line.

2. The memory device according to claim 1, wherein in the write operation, the driver circuit applies the second voltage to the second bit line during a first time, and then stops the application of the second voltage to the second bit line.

3. The memory device according to claim 1, wherein in a case where the memory cell transistor is set to be a program-target in the write operation, the sense amplifier applies a third voltage lower than the first voltage to the first bit line.

4. The memory device according to claim 1, further comprising:
a third bit line coupled between the sense amplifier and the first bit line; and
a third select transistor, one end and the other end of the third select transistor being coupled to the third bit line and the first bit line, respectively,
wherein the driver circuit is coupled to the first bit line.

5. The memory device according to claim 1, further comprising:
a third bit line coupled between the sense amplifier and the first bit line;
a third select transistor of a first conductivity type, one end and the other end of the third select transistor being coupled to the third bit line and the first bit line, respectively; and
a fourth bit line coupled to a gate of the third select transistor,
wherein the driver circuit includes a fourth select transistor of a second conductivity type that is different from the first conductivity type, one end of the fourth transistor being coupled to the first bit line, the second voltage being applied to the other end of the fourth transistor, and a gate of the fourth transistor being coupled to the fourth bit line.

6. The memory device according to claim 5, further comprising a sequencer configured to execute the write operation,
wherein in the write operation the sequencer is configured to:
apply a voltage of a first logical level to the fourth bit line in a case where the memory cell transistor is set to be the program-inhibit; and
apply a voltage of a second logical level different from the first logical level to the fourth bit line in a case where the memory cell transistor is set to be a program-target.

7. The memory device according to claim 5, further comprising an operation selection circuit,
wherein in the write operation the operation selection circuit is configured to:
apply a voltage of a first logical level to the fourth bit line in a case where an output voltage of the sense amplifier is lower than the first voltage; and
apply a voltage of a second logical level different from the first logical level to the fourth bit line in a case where the output voltage is equal to or higher than the first voltage.

8. The memory device according to claim 5, further comprising:
a first conductor layer;
a first contact; and
a second contact, wherein
the third select transistor includes a first semiconductor layer of a third conductivity type, a first gate insulating film on the first semiconductor layer, and a first gate electrode on the first gate insulating film,
the fourth select transistor includes a second semiconductor layer of a fourth conductivity type different from the third conductivity type, a second gate insulating film on the second semiconductor layer, and a second gate electrode on the second gate insulating film, the second semiconductor layer being provided at an equal height to the first semiconductor layer,
the first conductor layer is provided in a layer higher than the first semiconductor layer,
the first contact couples the first conductor layer and the first gate electrode; and
the second contact couples the first conductor layer and the second gate electrode.

9. The memory device according to claim 1, further comprising a substrate,
wherein the string includes a third semiconductor layer extending in a first direction parallel to a surface of the substrate, the third semiconductor layer including a portion functioning as a channel of the memory cell transistor.

10. The memory device according to claim 9, further comprising a first pillar provided to extend in a second direction crossing the first direction, wherein
the first pillar functions as the word line, and
a portion where the first pillar and the third semiconductor layer intersect functions as the memory cell transistor.
